(19) United States
(12) Patent Application Publication
(10) Pub. No.: US 2020/0091265 A1
(43) Pub. Date: Mar. 19, 2020

(54) ORGANIC EL DISPLAY DEVICE

(71) Applicant: TORAY INDUSTRIES, INC., Tokyo (JP)

(72) Inventors: Shinichi MATSUKI, Shiga (JP); Takeshi ARAI, Shiga (JP); Kazuto MIYOSHI, Shiga (JP)

(73) Assignee: TORAY INDUSTRIES, INC., Tokyo (JP)

(21) Appl. No.: 16/469,823

(22) PCT Filed: Dec. 22, 2017
(86) PCT No.: PCT/JP2017/046098

§ 371 Date: Jun. 14, 2019

(30) Foreign Application Priority Data
Dec. 26, 2016 (JP) 2016-251206

(51) Int. Cl. H01L 27/32; H01L 51/00; H01L 51/56; H01L 51/52

(52) U.S. Cl. CPC H01L 27/3272; H01L 51/004; H01L 51/0072; H01L 51/0073; H01L 2227/323; H01L 27/3246; H01L 27/3258; H01L 51/56; H01L 51/5284; H01L 51/0043

(57) ABSTRACT

An organic EL display device includes a photosensitive resin composition including an (A) alkali-soluble resin, a (B) coloring agent, a (C) radical polymerizable compound, and a (D) photopolymerization initiator. The (A) alkali-soluble resin is an (A-1) alkali-soluble resin having a carboxy group. A sum of the content of at least one of a metal element and a halogen element in a non-volatile component measured by time-of-flight secondary ion mass spectrometry in a cured product formed by curing the photosensitive resin composition is 1×10¹⁷ atom/cm³ or larger and 1×10²² atom/cm³ or smaller. In an organic EL element constituted of at least a substrate, a first electrode, a second electrode, a light emitting pixel, a flattening layer, and a pixel division layer, the photosensitive resin composition is arranged in at least one of the flattening layer and the pixel division layer.

### FIELD

The present invention relates to an organic EL display device including at least a substrate, a first electrode, a second electrode, light emitting pixels, a flattening layer, and a pixel division layer.

### BACKGROUND

In recent years, many products using an organic electroluminescent (hereinafter referred to as “EL”) display device have been developed in display devices having a thin display device such as a smart phone, a tablet PC, and a television set.

The organic EL display device is a self-light emission type device and thus visibility and contrast are lowered by the external light reflection when external light such as sunlight outdoors is incident. Therefore, a technique for reducing external light reflection has been required. Until now, a display device using a heat resistant resin film in which light transmittance at each of the wavelengths of 365 nm to 436 nm before thermal treatment is 50% or higher and light transmittance at any wavelengths of 365 nm to 436 nm after the heat treatment is 10% or lower has been developed as a highly reliable organic EL display that reduce occurrence of malfunctions due to entry of light into the device (for example, refer to Patent Literature 1). In addition, an organic EL display device having a colored film that is a cured product of a colored resin composition including an alkali-soluble polyimide resin having a specific structure, a coloring material, a polymer dispersing agent, and an organic solvent located onto at least one layer of a flattening layer on a driving circuit and an insulating layer on a first electrode has been developed (for example, refer to Patent Literature 2).

On the other hand, in an organic pigment-dispersed color filter, reduction in the voltage drop of the liquid crystal display element due to reduction in the content of sodium or the total content of sodium and potassium in the pixel to a low level has been known (for example, refer to Patent Literature 3). Moreover, in a pigment dispersing product including the nano-particles of an organic pigment, an organic pigment nano-particle dispersing product that improves display unevenness at the time of producing an liquid crystal display device by regulating the content of an alkali metal or alkaline earth metal in the dispersion has been developed (for example, refer to Patent Literature 4).

### CITATION LIST

### Patent Literature

Patent Literature 1: WO 2016/56451

Patent Literature 2: WO 2016/158672

Patent Literature 3: Japanese Patent Application Laid-open No. H7-198928

Patent Literature 4: Japanese Patent Application Laid-open No. 2008-7774

### SUMMARY

### Technical Problem

Generally, in order to divide each of the light emitting pixels, an insulating layer referred to as a pixel division layer located between the first electrode and the second electrode is formed in the organic EL display device and a flattening layer is formed on a thin film transistor (hereinafter, referred to as “TFT”). In order to prevent external light reflection on the organic EL display device, providing a light shielding property by coloring the pixel division layer or the flattening layer is effective and materials having the high light shielding property have been developed.

On the other hand, in recent years, a phenomenon referred to as pixel shrinkage in which light emission luminance is lowered from the terminal of the pixel or some of the lighting pixels are not lit has occurred in the organic EL display device. Therefore, higher reliability for reducing the pixel shrinkage has been required.

A problem of an insufficient light shielding property and reliability has still arisen even when the colored compositions described in Patent Literatures 1 to 4 are applied to the pixel division layer or the flattening layer of the organic EL display device. Therefore, an object of the present invention is to provide an organic EL display device having a high light shielding property and excellent reliability.

### Solution to Problem

The inventors of the present invention have found that the pixel shrinkage can be reduced and the light shielding property and the reliability can be significantly improved by setting the sum of the contents of metal elements and halogen elements in the cured film of a photosensitive resin composition including a coloring agent in a specific range. The present invention mainly includes the following constitution.

An organic EL display device includes: a photosensitive resin composition comprising an (A) alkali-soluble resin, a (B) coloring agent, a (C) radical polymerizable compound, and a (D) photopolymerization initiator. The (A) alkali-soluble resin is an (A-1) alkali-soluble resin having a carboxy group. A sum of content of at least one of a metal element and a halogen element in a non-volatile component measured by time-of-flight secondary ion mass spectrometry in a cured product formed by curing the photosensitive resin composition is 1×10¹⁷ atom/cm³ or larger and 1×10²² atom/cm³ or smaller. In an organic EL element constituted of at least a substrate, a first electrode, a second electrode, a light emitting pixel, a flattening layer, and a pixel division layer, the photosensitive resin composition is arranged in at least one of the flattening layer and the pixel division layer.

### Advantageous Effects of Invention

According to the present invention, an organic EL display device having a high light shielding property and excellent reliability can be provided.

### BRIEF DESCRIPTION OF DRAWINGS

FIG. 1 is a sectional view illustrating a TFT substrate having a flattening layer and a pixel division layer.

FIG. 2 is a process view illustrating the production process of the organic EL display device according to the present invention.

FIG. 3A is a schematic view (first view) of the production procedure of an organic EL display device in Examples.

FIG. 3B is a schematic view (second view) of the production procedure of the organic EL display device in Examples.

FIG. 3C is a schematic view (third view) of the production procedure of the organic EL display device in Examples.

FIG. 3D is a schematic view (fourth view) of the production procedure of the organic EL display device in Examples.

### DESCRIPTION OF EMBODIMENTS

Hereinafter, embodiments for carrying out the present invention (hereinafter referred to as “embodiments”) will be described in detail with reference to the attached drawings. Here, the present invention should not be limited by the embodiments alone described below.

The present invention includes an organic EL display device including an organic EL element constituted of at least a substrate, a first electrode, a second electrode, light emitting pixels, a flattening layer, and the pixel division layer, in which the flattening layer and/or a pixel division layer is made of a cured product of a photosensitive resin composition including an (A) alkali-soluble resin including an (A-1) alkali-soluble resin having a carboxy group, a (B) coloring agent, a (C) radical polymerizable compound, and a (D) photopolymerization initiator, and a sum of content of a metal element and a halogen element in a non-volatile component in the cured product of the photosensitive resin composition measured by time-of-flight secondary ion mass spectrometry is 1×10¹⁷ atom/cm³ or larger and 1×10²² atom/cm³ or smaller.

<Organic EL Display Device>

The organic EL display device according to the present invention includes at least the substrate, the first electrode, the second electrode, the light emitting pixels, the flattening layer, and the pixel division layer. The organic EL display device is preferably an active matrix-type organic EL display device having a plurality of pixels formed in a matrix pattern. The active matrix-type display device includes light emitting pixels on the substrate such as a glass and includes the flattening layer so that the flattening layer covers the lower parts of the light emitting pixels and the site other than the light emitting pixels. Moreover, the organic EL display device includes the first electrode located so as to cover at least the lower part of the light emitting pixels and the second electrode located so as to cover at least the upper part of the light emitting pixels on the flattening layer. In addition, in order to divide each of the light emitting pixels, the organic EL display device includes the insulating pixel division layer.

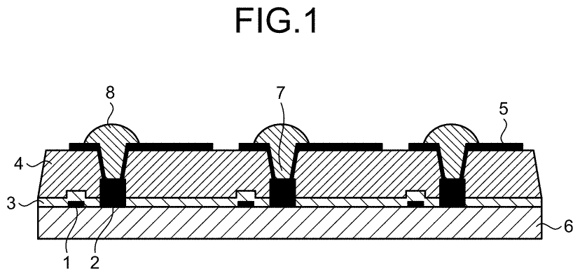

In FIG. 1, a sectional view of a TFT substrate having the flattening layer and the pixel division layer is illustrated. On the substrate 6, bottom gate type or top gate type TFTs 1 are located in a matrix shape. A TFT insulating layer 3 is formed so as to cover these TFTs 1. In addition, wirings 2 connected to TFTs 1 are located under the TFT insulating layer 3. Moreover, on the TFT insulating layer 3, contact holes 7 opening the wirings 2 and a flattening layer 4 are located, in a state where these components excluding the flattening layer 4 are embedded in the flattening layer 4. In the flattening layer 4, the openings are located so as to reach the contact holes 7 of the wirings 2. In addition, through the contact holes 7, ITOs 5 (transparent electrodes) are formed on the flattening layer 4 in a state where the ITOs 5 are connected to the wirings 2. Here, ITOs 5 act as the first electrodes of the organic EL display device. In addition, the pixel division layer 8 is formed so as to cover the peripheral border of the ITOs 5. This organic EL display device may be a top emission type organic EL display device emitting emitted light from the opposite side of the substrate 6 or may be a bottom emission type organic EL display device emitting emitted light from the side of the substrate 6.

In addition, a device formed by arranging organic EL display devices having each of the light emission peak wavelengths in red, green, and blue regions on the substrate 6 or a device formed by preparing a full-screen white organic EL display device and separately using a color filter in combination with this organic EL display device is referred to as a color display. In the color display, usually the peak wavelength of the displayed red light region is in the range of 560 nm to 700 nm, the peak wavelength of the green light region is in the range of 500 nm to 560 nm, and the peak wavelength of the blue light region is in the range of 420 nm to 500 nm.

<Method for Producing Organic EL Display Device>

The outline of a method for producing the organic EL display device according to the embodiment of the present invention will be described. In the organic EL display device, for example, the TFT (thin film transistor) 1 and the wiring 2 are formed on the substrate 6 and the flattening layer 4 is formed so as to cover the unevenness of these components. The organic EL display device can be obtained by forming the first electrode 5, the pixel division layer 8, and light emitting pixels, which are not illustrated, on the flattening layer 4 and further forming the second electrode, which is not illustrated, on the light emitting pixels. The flattening layer 4 and the pixel division layer 8 can be formed by, for example, applying the photosensitive resin composition described below, pattern-processing by photolithography, if necessary, and curing the photosensitive resin composition. In the case of the active matrix-type organic EL display device, the second electrode is generally formed in solid across the whole light emitting region. After forming the second electrode, sealing is preferably carried out. It is generally said that the organic EL display device is weak to oxygen and moisture. Therefore, the sealing is preferably carried out under atmosphere in which oxygen and moisture exist as little as possible in order to obtain a highly reliable display device.

<Substrate>

As the substrate, a glass substrate made of, for example, soda glass or alkali-free glass and a flexible substrate such as a polyethylene terephthalate film and a polyimide film are suitably used. The thickness of the glass substrate is preferably 0.5 mm or larger. As the material of the glass substrate, non-alkali glass and soda lime glass having barrier coating such as SiO₂ are preferable because the amount of ions eluted from the glass is small.

<First Electrode>

In order to efficiently inject holes into the organic layer and to extract light, the first electrode is preferably transparent or translucent. Examples of the material constituting the first electrode include electric conductive metal oxides such as zinc oxide, tin oxide, indium oxide, indium tin oxide (ITO), and indium zinc oxide (IZO), metals such as gold, silver, and chromium, inorganic electric conductive materials such as copper iodide and copper sulfide, electric conductive polymers such as polythiophene, polypyrrole, and polyaniline, and carbon nanotube and graphene. These materials may be used in combination of two or more of them or may have a laminated structure formed of different materials. In addition, the form of the material is not particularly limited. For example, the material may have fine structures such as metal mesh and silver nano-wire. Of these materials, ITO glass and Nesa glass are preferable.

The first electrode preferably has low resistance from the viewpoint of power consumption of the organic EL display device. For example, in the case of ITO substrate, the electrode functions as an element electrode when the electric resistance value is 300Ω/□ or lower. However, the substrate having an electric resistance value of about 10Ω/□ is now available and thus the substrate having a low resistance of 20Ω/□ or lower is more preferably used. The thickness of the first electrode can be appropriately selected in accordance with the electric resistance value and the thickness is commonly about 45 nm to 300 nm.

<Second Electrode>

The second electrode preferably allows electrons to be effectively injected into a light emitting layer. Examples of the material constituting the second electrode include metals such as platinum, gold, silver, copper, iron, tin, aluminum, and indium and alloys of these metals and low work function metals such as lithium, sodium, potassium, calcium, and magnesium. These materials may be used in combination of two or more of them or may have a laminated structure formed of different materials. Among these materials, materials including aluminum, silver, or magnesium as the main component are preferable from the viewpoints of an electric resistance value and easy film forming, stability of the film, light emission efficiency, and the like. The material preferably includes magnesium and silver. This allows electron injection into the light emitting layer to be facilitated and the driving voltage to be further reduced.

Examples of methods for forming the first electrode and the second electrode include resistance heating evaporation, electron beam evaporation, sputtering, ion plating, and coating.

Of the first electrode and the second electrode, the electrode used as a negative electrode preferably has a protection layer on the electrode. Examples of the material constituting the protection layer include inorganic materials such as silica, titania, and silicon nitride and organic polymer compounds such as polyvinyl alcohol, polyvinyl chloride, and hydrocarbon-based polymer compounds. In the case of the top emission structure in which light is extracted from the negative electrode side, the material constituting the protection layer is preferably a material having light transparency in the visible light region.

<Light Emitting Pixels>

The light emitting pixel is a part where the first electrode and second electrode arranged to face each other intersect and overlap. In the case where the pixel division layer is formed on the first electrode, the part is further restricted by the pixel division layer. The shape of the light emitting pixel is not particularly limited. The shape may be a rectangular shape or a circular shape and can be formed in any shapes depending on the shape of the pixel division layer. In the active matrix-type display, a part where a switching unit is formed may be arranged so as to occupy a part of the light emitting pixels and the shape of the light emitting pixels may also be in a form so that a part is missing.

Examples of the constitution of the light emitting pixel include a constitution made of the light emission layer alone and laminated structures such as 1) light emission layer/electron transport layer, 2) hole transport layer/light emitting layer, 3) hole transport layer/light emitting layer/electron transport layer, 4) hole injection layer/hole transport layer/light emitting layer/electron transport layer, 5) hole transport layer/light emitting layer/electron transport layer/electron injection layer, and 6) hole injection layer/hole transport layer/light emitting layer/electron transport layer/electron injection layer.

Moreover, a tandem type light emitting pixel in which the above laminated structures are laminated through intermediate layers may be employed. The intermediate layer is also referred to as an intermediate electrode, an intermediate electric conductive layer, a charge generating layer, an electron withdrawing layer, a connection layer, and an intermediate insulating layer. Examples of the constitution of the tandem type light emitting pixel include laminated structures including a charge generation layer as the inter mediate layer such as 7) hole transport layer/light emitting layer/electron transport layer/charge generation layer/hole transport layer/light emitting layer/electron transport layer and 8) hole injection layer/hole transport layer/light emitting layer/electron transport layer/electron injection layer/charge generation layer/hole injection layer/hole transport layer/light emitting layer/electron transport layer/electron injection layer. The material constituting the intermediate layer is preferably pyridine derivatives and phenanthroline derivatives.

In addition, each of the layers may be any of a single layer or multiple layers. Moreover, a layer (capping layer) using a capping material for improving the light emission efficiency due to an optical interference effect may be included on the light emitting pixel. The material constituting the capping layer is preferably aromatic amine derivatives.

<Hole Injection Layer>

The hole injection layer is inserted between a positive electrode and the hole transport layer, and is a layer that facilitates transfer of holes from the positive electrode into the hole transport layer. Existence of the hole injection layer between the hole transport layer and the positive electrode allows the light emitting pixel to be driven at a lower voltage and durability life to be improved. Moreover, carrier balance in the organic EL display device is improved and thus the light emission efficiency can be improved.

Examples of the material constituting the hole injection layer include carbazole derivatives such as 4,4′-bis(N-(3-methylphenyl)-N-phenylamino)biphenyl (TPD), 4,4′-bis(N-(1-naphthyl)-N-phenylamino)biphenyl (NPD), bis(N-arylcarbazole), and bis(N-alkylcarbazole). In the hole injection layer, these materials may be used in combination of two or more of them or may have a laminated structure formed of the different materials.

The hole injection layer is preferably further doped with an acceptor compound. The acceptor compound is a material constituting the hole injection layer and a material forming a charge transfer complex. Use of such an acceptor compound allows the electric conductivity of the hole injection layer to be improved, the driving voltage of the organic EL display device to be further reduced, and the light emission efficiency and durability life to be further improved.

Examples of the acceptor compound include metal oxides, organic compounds having a nitro group, a cyano group, a halogen, or a trifluoromethyl group in the molecule, quinone-based compounds, acid anhydride compounds, and fullerene. Of these compounds, the metal oxides or a cyano group-containing organic compounds are preferable because these compounds are easy to handle and easy to be deposited by evaporation.

<Hole Transport Layer>

The hole transport layer is a layer that transports holes injected from the positive electrode to the light emitting layer. The hole transport layer may be a single layer or may be constituted of a plurality of layers by laminating. The hole transport layer preferably has an ionization potential of 5.1 eV to 6.0 eV (a measured value of the evaporation-deposited film measured with AC-2 (manufactured by RIKEN KIKI CO., LTD.)), a high triplet energy level, a high hole transporting property, and thin film stability. The hole transport layer may be used as a hole transport material of the organic EL display device using a triplet light emitting material. Examples of the material constituting the hole transport layer include the exemplified materials as the materials for constituting the hole injection layer.

<Light Emitting Layer>

The light emitting layer is a layer that emits light by exiting a light emitting material due to recombination energy generated by the collision of holes and electrons. The light emitting layer may be a single layer or may be constituted of a plurality of layers by laminating. Each of the single layer and the multiple layer is formed of the light emitting materials (host material and dopant material). Each light emitting layer may be constituted of only any one of the host material or the dopant material or may be constituted by a combination of one or more host materials and one or more dopant materials. In other words, in each of light emitting layers, the host material or the dopant material alone may emit light or both of the host material and the dopant material may emit light. From the viewpoints of effectively using electric energy and achieving light emission with high color purity, the light emitting layer is preferably constituted of a combination of the host material and the dopant material. The dopant material may be included in the whole host material or may be included partially. From the viewpoint of reducing a concentration quenching phenomenon, the content of the dopant material in the light emitting layer is preferably 30 parts by weight or smaller and more preferably 20 parts by weight or smaller relative to 100 parts by weight of the host material. The light emitting layer can be formed by a method of co-evaporating the host material and the dopant material or a method of previously mixing the host material and the dopant material and thereafter evaporating the mixed material.

Examples of the dopant material constituting the light emitting material include condensed ring derivatives such as anthracene and pyrene, metal complex compounds such as tris(8-quinolinolate) aluminum, bisstyryl derivatives such as bis-styrylanthracene derivatives and di-styrylbenzene derivatives, tetraphenyl butadiene derivatives, dibenzofuran derivatives, carbazole derivatives, indolocarbazole derivatives, and polyphenylene vinylene derivatives.

Preferable examples of the dopant material that is used at the time of carrying out triplet light emission (phosphorescence) of the light emitting layer include metal complex compounds containing at least one metal selected from the group consisting of iridium (Ir), ruthenium (Ru), palladium (Pd), platinum (Pt), osmium (Os), and rhenium (Re). Ligands constituting the metal complex compounds can be appropriately selected depending on the required emission color, the organic EL display device performance, and the relation to the host compound and preferably have nitrogen-containing aromatic heterocycles such as phenylpyridine skeleton, a phenylquinoline skeleton, and carbene skeleton. Specific examples include tris(2-phenylpyridyl) iridium complex, bis(2-phenylpyridyl) (acetylacetonate) iridium complex, and tetraethylporphyrin platinum complex. The metal complex compound may be constituted of two or more of these ligands.

Examples of the host material constituting the light emitting material include compounds having a condensed aryl ring such as naphthalene, anthracene, phenanthrene, pyrene, chrysene, naphthacene, triphenylene, perylene, fluoranthene, fluorene, and indene. The light emitting material may be constituted by using two or more of these compounds.

Suitably usable examples of the host used at the time of carrying out triplet light emission (phosphorescence) of the light emitting layer include metal chelated oxinoid compounds, dibenzofuran derivatives, dibenzothiophene derivatives, carbazole derivatives, indolocarbazole derivatives, triazine derivatives, and triphenylene derivatives. Of these compounds, a compound having an anthracene skeleton or a pyrene skeleton is preferable because a high efficiency light emission can be easily achieved.

<Electron Transport Layer>

The electron transport layer is a layer that transports electrons injected from the negative electrode to the light emitting layer. High electron injection efficiency and effective transport of the injected electrons are desired for the electron transport layer. Therefore, the electron transport layer is preferably made of a substance having high electron affinity and electron mobility, excellent stability, and difficulty in generating impurity serving as traps during production and use. In particular, in the case where the film thickness of the electron transport layer is thick, the film quality easily deteriorates due to, for example, crystallization of low molecular weight compounds. Consequently, the compound preferably has a molecular weight of 400 or higher. Here, in the case where transportation balance between holes and electrons is considered, the effect of improving the light emission efficiency is equivalent to the case where the electron transport layer is constituted of a material having high electron transport capability, even when the electron transport layer is constituted of a material having not so high electron transport capability, if the electron transport layer mainly plays a role of effectively preventing the holes from the positive layer from flowing to the negative electrode side without recombination. Therefore, the electron transport layer in the present invention includes a hole blocking layer that efficiently prevents the holes from moving as the layer having the same meaning. The electron transport layer may be a single layer or may be a plurality of layers constituted by laminating.

Examples of the electron transport material constituting the electron transport layer include condensed polycyclic aromatic derivatives such as naphthalene and anthracene. The electron transport layer may be constituted of two or more of these compounds. Of these compounds, a compound having a heteroaryl ring structure containing electron-accepting nitrogen is preferable because the driving voltage is further reduced and high efficiency light emission is achieved.

The electron-accepting nitrogen referred to herein means a nitrogen atom forming a multiple bond to the adjacent atom. The nitrogen atom has high electronegativity and thus such a multiple bond has an electron-accepting property. Therefore, the aromatic heterocyclic ring containing electron-accepting nitrogen has high electron affinity. An electron transport material having the electron-accepting nitrogen can further reduce the driving voltage because the electron transport material having the electron-accepting nitrogen easily accepts electrons from the negative electrode having a high electron affinity. In addition, the electron transport material having the electron-accepting nitrogen increases the supply of electrons into the light emitting layer and increases recombination probability, resulting in improving light emission efficiency.

Examples of the heteroaryl ring containing the electron-accepting nitrogen include a triazine ring and a pyridine ring. As the compound having these heteroaryl ring structures, triazole derivatives such as N-naphthyl-2,5-diphenyl-1,3,4-triazole, bipyridine derivatives such as 2,5-bis(6′-(2′,2″-bipyridyl))-1,1-dimethyl-3,4-diphenylsilole, terpyridine derivatives such as 1,3-bis(4′-(2,2′:6′2″-terpyridinyl))benzene or two or more of these compounds are preferably used from the viewpoint of electron transport capability.

The electron transport layer may include a donor compound. Here, the donor compound refers to a compound that facilitates the injection of electrons from the negative electrode or the electron injection layer into the electron transport layer and further improves the electric conductivity of the electron transport layer by improving an electron injection barrier.

Examples of the donor compound include alkali metals, inorganic salts of alkali metals, complexes of alkali metals and organic substances, alkaline earth metals, inorganic salts of alkaline earth metals, or complexes of alkaline earth metals and organic substances.

As the donor compound, the inorganic salt or the complex with the organic substance is preferable than the metal alone due to easy evaporation in vacuum and excellent handling. The complex with the organic substance is more preferable because handling in the air is easy and the addition concentration is easily controlled.

The ionization potential of the electron transport layer is preferably 5.6 eV or higher and more preferably 5.6 eV or higher. On the other hand, the ionization potential of the electron transport layer is preferably 8.0 eV or lower and more preferably 7.0 eV or lower.

Examples of a method for forming each of the above-described layers constituting the organic EL display device include a resistance heating evaporation method, an electron beam evaporation method, a sputtering method, a molecular layer deposition method, and a coating method. Of these methods, from the viewpoint of the organic EL display device characteristics, the resistance heating evaporation method and the electron beam evaporation method are preferable.

The total thickness of the organic layers including the hole injection layer, the hole transport layer, the light emitting layer, and the electron transport layer can be appropriately selected depending on the resistance value of the light emitting material and is preferably 1 nm to 1,000 nm. Each thickness of the hole injection layer, the hole transport layer, the light emitting layer, and the electron transport layer is preferably 1 nm or larger and more preferably 5 nm or larger. On the other hand, each thickness of the hole injection layer, the hole transport layer, the light emitting layer, and the electron transport layer is preferably 200 nm or smaller and more preferably 100 nm or smaller.

<Flattening Layer and Pixel Division Layer>

The flattening layer and/or the pixel division layer is made of the cured product of the photosensitive resin composition described below and the sum of content of the metal element and halogen element in the non-volatile component measured by the time-of-flight secondary ion mass spectrometry in the cured product is 1.0×10¹⁷ atom/cm³ or larger and 1.0×10²² atom/cm³ or smaller. By including the metal element and halogen element in the cured product in trace amounts, the electric conductivity of the ITO electrode to be a pattern opening part is improved due to the metal element and/or halogen element attached on the substrate in trace amounts during the formation of the flattening layer and/or the pixel division layer. Consequently, the driving voltage of the organic EL display device can be reduced and the reliability can be improved. In addition, by element trapping effect in which these elements form salts with the (A-1) alkali-soluble resin having the carboxy group, electrode corrosion such as alkali migration originated from excessive metal elements and halogen elements and light emission luminance decrease and pixel shrinkage caused by the electrode corrosion are reduced and thus the reliability of the organic EL display device can be improved. The flattening layer and/or the pixel division layer having a sum of content of the metal element and/or the halogen element of smaller than 1.0×10¹⁷ atom/cm³ tends to have low electric conductivity of the ITO electrode to be a pattern opening part and to become high voltage in the case where the organic EL display device is driven for a long period of time. Consequently, the reliability deteriorates. On the other hand, the flattening layer and/or the pixel division layer having a sum of content of the metal element and/or the halogen element of larger than 1.0×10²² atom/cm³ tends to cause electrode corrosion at the pattern opening part due to the excessive metal elements and halogen elements that cannot be trapped by the element trap effect. Consequently, the reliability deteriorates due to decrease in the light emission luminance and the pixel shrinkage when the organic EL display device is driven for a long period of time.

In the present invention, examples of a method of setting the sum of content of the metal element and/or the halogen element to the above range include a method of using the photosensitive resin composition described below.

<Metal Element>

The metal element in the present invention refers to an element that indicates a property of a metal and a free ion is also included. In the photosensitive resin composition described below, an alkali metal element and an alkaline earth metal element is preferably included because these elements are easily trapped by salt formation and interaction with the carboxy group in the case where the (A-1) alkali-soluble resin having a carboxy group is included as the (A) alkali-soluble resin. The alkali metal element is more preferably included and sodium and potassium is further preferably included. The sum of the contents of the alkali metal element and the alkaline earth metal element is preferably 1.0×10¹⁷ atom/cm³ or larger. The photosensitive resin composition having this sum of the contents can further reduce the driving voltage of the organic EL display device and can further improve the reliability of the organic EL display device. On the other hand, the sum of the contents of the alkali metal element and the alkaline earth metal element is preferably 5.0×10²¹ atom/cm³ or smaller. The photosensitive resin composition having this sum of the contents can further improve the reliability of the organic EL display device. In addition, the sum of the contents of the alkali metal elements is preferably 1.0×10¹⁷ atom/cm³ or larger. The photosensitive resin composition having this sum of the contents can further reduce the driving voltage of the organic EL display device and can further improve the reliability of the organic EL display device. On the other hand, the sum of the contents of the alkali metal elements is preferably 4.5×10²¹ atom/cm³ or smaller. The photosensitive resin composition having this sum of the contents can further improve the reliability of the organic EL display device. In addition, the sum of the contents of sodium and potassium is preferably 1.0×10¹⁷ atom/cm³ or larger. The photosensitive resin composition having this sum of the contents can reduce the driving voltage of the organic EL display device. In addition, the sum of the contents of sodium and potassium is preferably 4.0×10²¹ atom/cm³ or smaller. The photosensitive resin composition having this sum of the contents can further improve the reliability of the organic EL display device.

<Halogen Elements>

The halogen element in the present invention refers to an element belonging to Group 17 in the periodic table and a free ion is also included. In photosensitive resin composition described below, an amino group and/or an amide group can form a salt with the halogen element and can trap the halogen element in the case where an (A-1c) alkali-soluble resin having a carboxy group and an amino group and/or an amide group is included as the (A) alkali-soluble resin. Consequently, the reliability of the organic EL display device can be further improved. Of halogen elements, chlorine is preferably included because chlorine is easily trapped with the amino group and/or amide group. The sum of the contents of chlorine is preferably 1.0×10¹⁷ atom/cm³ or larger. The photosensitive resin composition having this sum of the contents can further reduce the driving voltage of the organic EL display device. On the other hand, the sum of the contents of chlorine is preferably 5.0×10²¹ atom/cm³ or smaller. The photosensitive resin composition having this sum of the contents can further improve the reliability of the organic EL display device.

<Method for Quantifying Metal Elements and Halogen Elements>

Metal elements and halogen elements in non-volatile components of the cured product of the photosensitive resin composition can be quantified by the following method. First, the specific amount of a known target element is injected into the cured film and the relative sensitivity factor (RSF) is calculated from the following equation by using the IMX-3500RS (manufactured by ULVAC, Inc.). In order to improve the sensitivity (atom/cm³) of TOF-SIMS described below, the ion injection amount is preferably 1.0×10¹³ atom/cm² to 5.0×10¹⁵ atom/cm².

$$RSF = \frac{{φ}_{0}}{{\sum }_{i} ( {I}_{i} - {I}_{BG} )} \times \frac{1}{Δ {d}_{0}} \times {I}_{ref}$$

ϕ₀: Ion injection amount (atom/cm²)
Δd₀: Depth per measurement cycle (cm)
Iᵢ: Ion intensity of impurity (counts)
I_{BG}: Background intensity (counts)
I_{ref}: Ion intensity of cured film (counts)

The individual metal element and halogen element (target element) concentrations in the cured film can be quantified from the TOF-SIMS analysis in accordance with the following equation based on the resultant relative sensitivity factor.

Target element concentration=RSF (atom/cm³)×Ion intensity of target element (counts)/Ion intensity of the cured film (counts).

Here, the position used for calculation of the quantification is a depth of 0.5 μm from the surface of the cured film.

<Pixel Division Layer Opening Ratio>

The pixel division layer opening ratio of the display area of the organic EL display device according to the present invention is preferably 20% or lower. Here, the pixel division layer opening ratio refers to the area ratio of the area of the pixel division layer opening part to the area of the whole organic EL display device. Progress of higher definition of pixels causes the pixel division layer opening ratio to be lowered and the influence of the pixel shrinkage to be significant. The organic EL display device according to the present invention can reduce the light emission luminance decrease and the pixel shrinkage and can improve the reliability of organic EL display devices. Therefore, the organic EL display device exhibits particularly remarkable effects in the case where the pixel division layer opening ratio is 20% or lower, in which the pixel shrinkage has significant effects.

<Photosensitive Resin Composition>

Subsequently, the photosensitive resin composition as the raw material for the cured film constituting the flattening layer and/or the pixel division layer will be described. The photosensitive resin composition includes an (A) alkali-soluble resin, a (B) coloring agent, a (C) radical polymerizable compound, and a (D) photopolymerization initiator. The photosensitive resin composition may further include other components.

<(A) Alkali-Soluble Resin>

The (A) alkali-soluble resin in the present invention refers to a resin having an alkali dissolution rate of 1 nm/min or higher. The alkali dissolution rate is a film thickness decrease value measured by developing the pre-baked film of the resin with a 2.38% by mass TMAH aqueous solution for 60 seconds and rinsing the developed film with water for 30 seconds. From the viewpoint of developability, the (A) alkali-soluble resin preferably includes the (A-1) alkali-soluble resin having the carboxy group.

<(A-1) Alkali-Soluble Resin Having Carboxy Group>

As the (A-1) alkali-soluble resin having the carboxy group, an (A-1a) acrylic resin, an (A-1b) cardo-based resin, and an (A-1c) alkali-soluble resin having a carboxy group and an amino group and/or an amide group are preferable from the viewpoint of easiness of introduction of a carboxylic acid during resin synthesis. The (A-1) alkali-soluble resin having the carboxy group may include two or more of these resins. Examples of the (A-1c) alkali-soluble resin having the carboxy group and the amino group and/or the amide group include a polyimide precursor and an acrylic resin. In the case where the acrylic resin or the polyimide precursor has a carboxy group and an amino group and/or an amide group, however, the resin or the precursor is determined to be the (A-1c) alkali-soluble resin having the carboxy group and the amino group and/or the amide group. In particular, from the viewpoint of alkali developing margin, the (A-1a) acrylic resin and the (A-1b) cardo-based resin are more preferable. The carboxylic acid equivalent of the (A-1) alkali-soluble resin having the carboxy group is preferably 400 g/mol or higher from the viewpoints of improving the trapping property of the metal element and halogen element and further improving the reliability of the organic EL display device. In addition, the carboxylic acid equivalent of the (A-1) alkali-soluble resin having the carboxy group is preferably 1,000 g/mol or lower from the viewpoint of improving the residual film ratio during the development.

<(A-1a) Acrylic Resin>

The (A-1a) acrylic resin preferably has an ethylenically unsaturated double bond. The (A-1a) acrylic resin is a resin in which the ethylenically unsaturated double bond is easily introduced in side chains branched from the main chain of the resin. In the case of the (A-1a) acrylic resin having the ethylenically unsaturated double bond, the (A-1a) acrylic resin is photocurable and is cured by exposure to form the three-dimensional crosslinked structure of the carbon-carbon bond. Therefore, the sensitivity during exposure can be improved. From the viewpoint of improving sensitivity during exposure and mechanical properties of the cured film, the (A-1a) acrylic resin preferably contains the structure unit represented by the following general formula (61) and/or the structure unit represented by the following general formula (62).

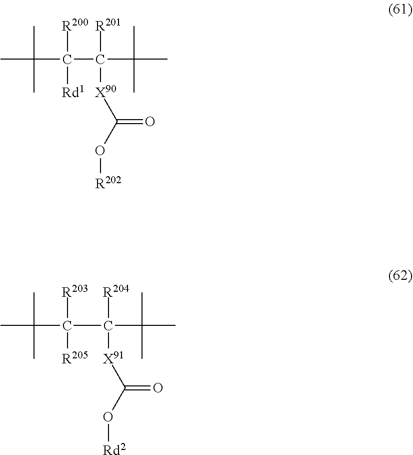

Rd¹ in the general formula (61) and Rd² in the general formula (62) each independently represent an alkyl group having a carbon number of 1 to 10, a cycloalkyl group having a carbon number of 4 to 15, or an aryl group having a carbon number of 6 to 15, substituted with an organic group having an ethylenically unsaturated double bond, and R²⁰⁰ to R²⁰⁵ each independently represent hydrogen, an alkyl group having a carbon number of 1 to 10, a cycloalkyl group having a carbon number of 4 to 10, or an aryl group having a carbon number of 6 to 15. X⁹⁰ and X⁹¹ each independently represent a direct bond, an alkylene group having a carbon number of 1 to 10, a cycloalkylene group having a carbon number of 4 to 10, and an arylene group having a carbon number of 6 to 15.

Rd¹ in the general formula (61) and Rd² in the general formula (62) each independently preferably represent an alkyl group having a carbon number of 1 to 6, a cycloalkyl group having a carbon number of 4 to 10, or an aryl group having a carbon number of 6 to 10, substituted with an organic group having an ethylenically unsaturated double bond. R²⁰⁰ to R²⁰⁵ each independently preferably represent hydrogen, an alkyl group having a carbon number of 1 to 6, a cycloalkyl group having a carbon number of 4 to 7, or an aryl group having a carbon number of 6 to 10. In addition, X⁹⁰ and X⁹¹ each independently preferably represent a direct bond, an alkylene group having a carbon number of 1 to 6, a cycloalkylene group having a carbon number of 4 to 7, and an arylene group having a carbon number of 6 to 10.

<(A-1b) Cardo-Based Resin>

The (A-1b) cardo-based resin is a thermosetting resin having a structure in which a main chain and a bulky side chain having a cyclic structure such as a fluorene ring having high heat resistance and a rigid structure are connected by a single atom. By including such an (A-1b) cardo-based resin, the heat resistance of the cured product can be improved.

The (A-1b) cardo-based resin preferably has an ethylenically unsaturated double bond. The (A-1b) cardo-based resin is a resin in which the ethylenically unsaturated double bond can be easily introduced in side chains branched from the main chain of the resin. In the case of the (A-1b) cardo-based resin having the ethylenically unsaturated double bond, the (A-1b) cardo-based resin is photocurable and is UV cured by exposure to form the three-dimensional crosslinked structure of carbon-carbon bonds. Therefore, the sensitivity during exposure can be improved.

<(A-1c) Alkali-Soluble Resin Having Carboxy Group and an Amino Group and/or Amide Group>

The (A-1c) alkali-soluble resin having the carboxy group and the amino group and/or the amide group more effectively traps the metal element with the carboxy group and the halogen element with the amine structure and/or the amide structure and thus this alkali-soluble resin further improves the reliability of the organic EL display device. Moreover, this alkali-soluble resin can improve the dispersion stability of the (B) coloring agent described below. The amino group is preferably a tertiary amino group and the tertiary amino group can improve the trapping property of the halogen element and the dispersion stability of the coloring agent. Examples of the alkali-soluble resin having the carboxy group and the amino group and/or the amide group include a polyimide precursor and an acrylic resin. As an example, the polyimide precursor will be described below.

The polyimide precursor has a tetracarboxylic acid and/or a derivative residue thereof and a diamine and/or a derivative residue thereof. The polyimide precursor can be obtained by reacting, for example, a tetracarboxylic acid, a corresponding tetracarboxylic dianhydride, or a tetracarboxylic acid diester dichloride with a diamine, a corresponding diisocyanate compound, or a trimethylsilylated diamine. Examples of the polyimide precursor include a polyamic acid, a polyamic acid ester, a polyamic acid amide, and a polyisoimide. The polyimide precursor is a thermosetting resin and provides the (A-2a) polyimide resin described below by dehydration ring closure by thermal curing at high temperature to form imide bonds providing high heat resistance. From the viewpoint of improving heat resistance of the cured film and the resolution after development, the polyimide precursor preferably contains a structure unit represented by the following general formula (3).

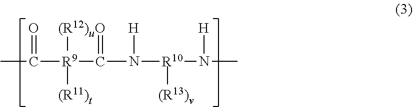

In the general formula (3), R⁹ represents a 4-valent to 10-valent organic group and Rⁿ represents a 2-valent to 10-valent organic group. R¹¹ represents a group represented by the following general formula (5) or the following general formula (6); R¹² represents a phenolic hydroxy group, a sulfonic acid group, or a mercapto group; R¹³ represents a phenolic hydroxy group, a sulfonic acid group, a mercapto group, or a group represented by the following general formula (5) or the following general formula (6); t represents an integer of 2 to 8 and u represents an integer of 0 to 6, v represents an integer of 0 to 8 and 2≤t+u≤8.

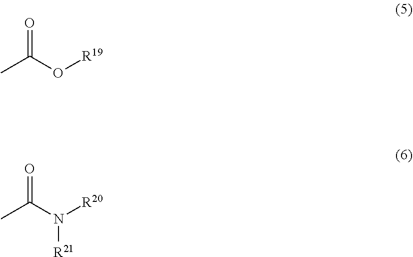

R¹⁹ in the general formula (5) and R²⁰ and R²¹ in the general formula (6) each independently represent hydrogen, an alkyl group having a carbon number of 1 to 10, an acyl group having a carbon number of 2 to 6, or an aryl group having a carbon number of 6 to 15. R¹⁹ in the general formula (5) and R²⁰ and R²¹ in the general formula (6) each independently preferably represent hydrogen, an alkyl group having a carbon number of 1 to 6, an acyl group having a carbon number of 2 to 4, or an aryl group having a carbon number of 6 to 10. The alkyl group, the acyl group, and the aryl group may contain a substituent.

In the general formula (3), R⁹ represents a tetracarboxylic acid and/or a derivative residue thereof and R¹⁰ represents a diamine and/or a derivative residue thereof. Examples of the tetracarboxylic acid derivative include tetracarboxylic dianhydrides, tetracarboxylic acid dichlorides, and tetracarboxylic acid active diesters. Examples of the diamine derivative include diisocyanate compounds and trimethylsilylated diamines.

In the general formula (3), R⁹ preferably has an aliphatic structure having a carbon number of 2 to 20, an alicyclic structure having a carbon number of 4 to 20 and/or an aromatic structure having a carbon number of 6 to 30 and more preferably has an aliphatic structure having a carbon number of 4 to 15, an alicyclic structure having a carbon number of 4 to 15 and/or an aromatic structure having a carbon number of 6 to 25. In addition, R¹⁰ preferably has an aliphatic structure having a carbon number of 0.2 to 20, an alicyclic structure having a carbon number of 4 to 20 and/or an aromatic structures having a carbon number of 6 to 30 and more preferably has an aliphatic structure having a carbon number of 4 to 15, an alicyclic structure having a carbon number of 4 to 15 and/or an aromatic structures having a carbon number of 6 to 25. v is preferably an integer of 1 to 8. The aliphatic structure, alicyclic structure, and aromatic structure may have a hetero atom and may have a substituent.

Examples of the aliphatic structures R⁹ and R¹⁰ in the general formula (3) include an ethane structure, a n-butane structure, a n-pentane structure, a n-hexane structure, a n-decane structure, a 3,3-dimethylpentane structure, a di-n-butyl ether structure, a di-n-butyl ketone structure, and a di-n-butyl sulfone structure. In addition, examples of the substituent of the aliphatic structure include a halogen atom and an alkoxy group. Examples of the aliphatic structure having a substituent include 3,3-bis(trifluoromethyl)pentane structure and 3-methoxypentane structure.

Examples of the alicyclic structure of R⁹ and R¹⁰ in the general formula (3) include a cyclobutane structure, a cyclopentane structure, a cyclohexane structure, an ethylcyclohexane structure, a tetrahydrofuran structure, a bicyclohexyl structure, a 2,2-dicyclohexylpropane structure, a dicyclohexyl ether structure, a dicyclohexyl ketone structure, and a dicyclohexyl sulfone structure. In addition, examples of the substituent include a halogen atom and an alkoxy group. Examples of the alicyclic structure having a substituent group include a 1,1-dicyclohexyl-1,1-bis(trifluoromethyl)methane structure and a 1,1-dicyclohexyl-1-methoxymethane structure.

Examples of the aromatic structure of R⁹ and R¹⁰ in the general formula (3) include a benzene structure, an ethylbenzene structure, a naphthalene structure, a 1,2,3,4-tetrahydronaphthalene structure, a fluorene structure, a biphenyl structure, a terphenyl structure, a 2,2-diphenylpropane structure, a diphenyl ether structure, a diphenyl ketone structure, a diphenyl sulfone structure, and a 9,9-diphenylfluorene structure. In addition, examples of the substituent include a halogen atom and an alkoxy group. Examples of the aromatic structure having a substituent include a 1,1-diphenyl-1,1-bis (trifluoromethyl)methane structure and a 1,1-diphenyl-1-methoxymethane structure.

<(A-2) Alkali-Soluble Resin Having Phenolic Hydroxy Group>

From the viewpoint of the developing margin and pattern formation of the cured film, the photosensitive resin composition used in the present invention preferably includes an (A-2) alkali-soluble resin having the phenolic hydroxy group in addition to the (A-1) alkali-soluble resin having the carboxy group. Examples of the (A-2) alkali-soluble resin having the phenolic hydroxy group include a (A-2a) polyimide resin, a (A-2b) polybenzoxazole resin, a (A-2c) polybenzoxazole precursor, and a novolac resin. Two or more of these resins may be included. Of these resins, from the viewpoint of heat resistance, the (A-2a) polyimide resin and the (A-2b) polybenzoxazole resin are preferable. Here, the (A-2a) polyimide resin in the present invention is a resin including a structure unit made of an imide bond as the main component and belonging to the (A-2) alkali-soluble resin having the phenolic hydroxy group even when the resin has a carboxy group as a residue of an imide ring closure reaction.

The photosensitive resin composition used in the present invention preferably includes the (A-1) alkali-soluble resin having the carboxy group in an amount of 5 parts by weight or larger relative to 100 parts by weight of the total amount of the (A-1) alkali-soluble resin having the carboxy group and the (A-2) alkali-soluble resin having the phenolic hydroxy group. This photosensitive resin composition can improve pattern processability during development. On the other hand, the photosensitive resin composition preferably includes the (A-1) alkali-soluble resin having the carboxy group in an amount of 40 parts by weight or smaller. This photosensitive resin composition can improve the residual film ratio during development.

Mw of the (A-2) alkali-soluble resin having the phenolic hydroxy group used in the present invention is preferably 500 or higher, more preferably 1,000 or higher, and further preferably 1,500 or higher in terms of polystyrene measured by GPC. The (a-2) alkali-soluble resin having the phenolic hydroxy group having Mw within this range can improve the resolution after development.

On the other hand, Mw is preferably 100,000 or lower, more preferably 50,000 or lower, and further preferably 30,000 or lower. The (a-2) alkali-soluble resin having the phenolic hydroxy group having Mw within this range can improve a leveling property during application and the pattern processability with an alkali development liquid.

<(A-2a) Polyimide Resin>

The (A-2a) polyimide resin has a tetracarboxylic acid and/or a derivative residue thereof and a diamine and/or a derivative residue thereof. Examples of the (A-2a) polyimide resin include the imide compound of the polyimide precursor exemplified as (A1-c) and the (A-2a) polyimide resin can be obtained by the reaction of the polyimide precursor using heating, an acid, a base, or the like to carry out dehydration ring closure. From the viewpoint of improving the heat resistance of the cured film, the (A-2a) polyimide resin preferably includes a structure unit represented by the following general formula (1).

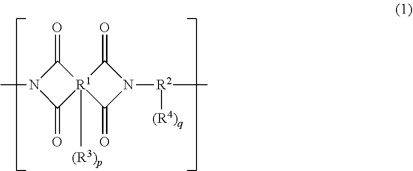

In the general formula (1), R¹ represents a 4-valent to 10-valent organic group and R² represents a 2-valent to 10-valent organic group. R³ and R⁴ each independently represent a phenolic hydroxy group, a sulfonic acid group, a mercapto group, and a group represented by the general formula (5) or the general formula (6). p represents an integer of 0 to 6 and q represents an integer of 0 to 8.

R¹ in the general formula (1) represents a tetracarboxylic acid and/or a derivative residue thereof and R² represents a diamine and/or a derivative residue thereof. Examples of the tetracarboxylic acid derivatives include tetracarboxylic dianhydrides, tetracarboxylic acid dichlorides, and tetracarboxylic acid active diesters. Examples of the diamine derivative include diisocyanate compounds and trimethylsilylated diamine.

In the general formula (1), R¹ is preferably a 4-valent to 10-valent organic group having an aliphatic structure having a carbon number of 2 to 20, an alicyclic structure having a carbon number of 4 to 20, and/or an aromatic structures having a carbon number of 6 to 30 and more preferably a 4-valent to 10-valent organic group having an aliphatic structure having a carbon number of 4 to 15, an alicyclic structure having a carbon number of 4 to 15 and/or an aromatic structures having a carbon number of 6 to 25. In addition, R² is preferably a 2-valent to 10-valent organic group having an aliphatic structure having a carbon number of 2 to 20, an alicyclic structure having a carbon number of 4 to 20, and/or an aromatic structures having a carbon number of 6 to 30 and more preferably a 2-valent to 10-valent organic group having an aliphatic structure having a carbon number of 4 to 15, an alicyclic structure having a carbon number of 4 to 15, and/or an aromatic structures having a carbon number of 6 to 25. q is preferably an integer of 1 to 8. The aliphatic structure, alicyclic structure, and aromatic structure may have a hetero atom and may have a substituent.

Examples of the aliphatic structure, the alicyclic structure, and the aromatic structure of R¹ and R² in the general formula (1) include the aliphatic structure, the alicyclic structure, and the aromatic structure of R⁹ and R¹⁰ in the general formula (3) exemplified above.

The (A-2a) polyimide resin preferably includes the structure unit represented by the general formula (1) as the main component. In the total structure units of the (A-2a) polyimide resin, the structure unit represented by the general formula (1) is preferably included in an amount of 50 mol % to 100 mol %. The polyimide resin having the content of the structure unit represented by the general formula (1) within the above range can improve the heat resistance of the cured product. The content of the structure unit represented by the general formula (1) is more preferably 60 mol % or larger and further preferably 70 mol % or larger.

<(A-2b) Polybenzoxazole Resin>

The (A-2b) polybenzoxazole resin has a dicarboxylic acid and/or a derivative residue thereof and a bis-aminophenol compound and/or a derivative residue thereof. Examples of the (A-2b) polybenzoxazole resin include dehydration ring closure products of the (A-2c) polybenzoxazole precursors described below and can be obtained by the dehydration ring closure of the (A-2c) polybenzoxazole precursors with heating, phosphoric acid anhydride, a base, a carbodiimide compound, or the like. From the viewpoint of improving the heat resistance of the cured film, the (A-2b) polybenzoxazole resin preferably includes a structure unit represented by the following general formula (2).

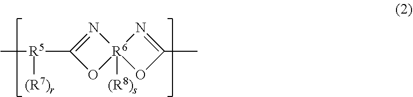

In the general formula (2), R⁵ represents a 2-valent to 10-valent organic group and R⁶ represents a 4-valent to 10-valent organic group having an aromatic structure. R⁷ and R⁶ each independently represent a phenolic hydroxy group, a sulfonic acid group, or a mercapto group. r represents an integer of 0 to 8 and s represents an integer of 0 to 6.

R⁵ in the general formula (2) represents a dicarboxylic acid and/or a derivative residue thereof and R⁶ represents a bisaminophenol compound and/or a derivative residue thereof. Examples of the dicarboxylic acid derivative include dicarboxylic acid anhydrides, dicarboxylic acid chlorides, dicarboxylic acid active esters, tricarboxylic acid anhydrides, tricarboxylic acid chlorides, tricarboxylic acid active esters, and diformyl compounds.

In the general formula (2), R⁵ is preferably a 2-valent to 10-valent organic group having an aliphatic structure having a carbon number of 2 to 20, an alicyclic structure having a carbon number of 4 to 20 and/or an aromatic structures having a carbon number of 6 to 30 and more preferably a 2-valent to 10-valent organic group having an aliphatic structure having a carbon number of 4 to 15, an alicyclic structure having a carbon number of 4 to 15 and/or an aromatic structures having a carbon number of 6 to 25. In addition, R⁶ is preferably a 4-valent to 10-valent organic group having an aromatic structure having a carbon number of 6 to 30 and more preferably 4-valent to 10-valent organic group having an aromatic structure having a carbon number of 6 to 25. s is preferably an integer of 1 to 8. The aliphatic structure, alicyclic structure, and aromatic structure may have a hetero atom and may have a substituent.

Examples of the aliphatic structure, the alicyclic structure, and the aromatic structure of R⁵ and R⁶ in the general formula (2) include the aliphatic structure, the alicyclic structure, and the aromatic structure of R⁹ and R¹⁰ in the general formula (3) exemplified above.

<(A-2c) Polybenzoxazole Precursor>

The (A-2c) polybenzoxazole precursor has a dicarboxylic acid and/or a derivative residue thereof and a bis-aminophenol compound and/or a derivative residue thereof. The (A-2c) polybenzoxazole precursor can be obtained by reacting, for example, a dicarboxylic acid, a corresponding dicarboxylic acid dichloride, or dicarboxylic acid active diester with a bis-aminophenol compound or the like as the diamine. Examples of the (A-2c) polybenzoxazole precursor include polyhydroxy amides. From the viewpoint of improving heat resistance of the cured film and the resolution after development, the (A-2c) polybenzoxazole precursor preferably contains a structure unit represented by the following general formula (4).

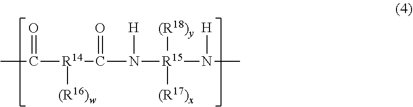

In the general formula (4), R¹⁴ represents a 2-valent to 10-valent organic group and Rⁿ represents a 4-valent to 10-valent organic group having an aromatic structure. R¹⁶ represents a phenolic hydroxy group, a sulfonic acid group, or a mercapto group, R¹⁷ represents a phenolic hydroxy group, and Rⁿ represents a sulfonic acid group or a mercapto group. w represents an integer of 0 to 8, x represents an integer of 2 to 8, y represents an integer of 0 to 6, and 2≤x+y≤8.

R¹⁴ in the general formula (4) represents a dicarboxylic acid and/or a derivative residue thereof and R¹⁵ represents a bis-aminophenol compound and/or a derivative residue thereof. Examples of the dicarboxylic acid derivative include dicarboxylic acid anhydrides, dicarboxylic acid chlorides, dicarboxylic acid active esters, tricarboxylic acid anhydrides, tricarboxylic acid chlorides, tricarboxylic acid active esters, and diformyl compounds.

In the general formula (4), R¹⁴ is preferably a 2-valent to 10-valent organic group having an aliphatic structure having a carbon number of 2 to 20, an alicyclic structure having a carbon number of 4 to 20 and/or an aromatic structures having a carbon number of 6 to 30 and more preferably a 2-valent to 10-valent organic group having an aliphatic structure having a carbon number of 4 to 15, an alicyclic structure having a carbon number of 4 to 15 and/or an aromatic structures having a carbon number of 6 to 25. In addition, R¹⁵ is preferably a 4-valent to 10-valent organic group having an aromatic structure having a carbon number of 6 to 30 and more preferably a 4-valent to 10-valent organic group having an aromatic structure having a carbon number of 6 to 25. The aliphatic structure, alicyclic structure, and aromatic structure may have a hetero atom and may have a substituent exemplified above.

Examples of the aliphatic structure, the alicyclic structure, and the aromatic structure of R¹⁴ and R¹⁵ in the general formula (4) include the aliphatic structure, the alicyclic structure, and the aromatic structure of R⁹ and R¹⁰ in the general formula (3).

<(A-2d) Novolac Resin>

The (A-2d) novolac resin has an aromatic structure derived from a phenolic compound. The (A-2d) novolac resin can be obtained by reacting the phenol compound with an aldehyde compound or a ketone compound. These compounds are preferably reacted in the presence of an acid catalyst in a solvent or without a solvent. In the case where the aldehyde compound and/or ketone compound has an aromatic structure, the novolac resin also has the aromatic structure derived therefrom. By containing the (A-2d) novolac resin, the heat resistance of the resultant cured product can be improved.

The (A-2d) novolac resin having a phenolic hydroxy group as the alkali-soluble group allows the alkali development margin to be improved. The (A-2d) novolak resin may further include a weak acidic group such as a hydroxy imide group in addition to the phenolic hydroxy group.

Examples of the phenol compounds include phenol, o-cresol, m-cresol, p-cresol, 2,5-xylenol, 3,5-xylenol, 2-ethylphenol, 3-ethylphenol, 4-ethylphenol, 4-n-propylphenol, 4-n-butylphenol, 4-t-butylphenol, 1-naphthol, 2-naphthol, 4,4′-dihydroxybiphenyl, 2,2-bis(4-hydroxyphenyl)propane, catechol, resorcinol, 1,4-hydroquinone, pyrogallol, 1,2,4-benzene triol, and phloroglucinol.

Examples of the aldehyde compounds include formaldehyde, paraformaldehyde, acetaldehyde, paraldehyde, propionaldehyde, benzaldehyde, and salicylaldehyde.

Examples of the ketone compound include acetone, methyl ethyl ketone, methyl isobutyl ketone, acetophenone, and benzophenone.

<(B) Coloring Agent>

Examples of the (B) coloring agent include an (B-1) organic pigment, an (B-2) inorganic pigment, and a (B-3) dye. The coloring agent may include two or more of these compounds. Of these coloring agents, from the viewpoints of heat resistance and reliability, the (B-1) organic pigment and the (B-2) inorganic pigment are preferable and, from the viewpoint of setting the contents of the metal element and the halogen element in the desired range described above, the (B-1) organic pigment is more preferable.

Examples of the means of setting the sum of the contents of the metal element and halogen element included in the cured film of the photosensitive resin composition used in the present invention include a method for using the (B-1) organic pigment including the metal element such as copper and the halogen element such as chlorine or bromine. In order to set the sum of the contents of the metal element and the halogen element, previous purification of the pigment dispersion liquid including the (B-1) organic pigment with an ion-exchange resin or a cation exchange resin and washing the (B-1) organic pigment several times with purified water and drying the washed organic pigment are preferable.

<(B-1) Organic Pigment>

Examples of the (B-1) organic pigment include diketopyrrolopyrrole-based pigments, azo-based pigments such as azo, disazo, and polyazo pigments, phthalocyanine-based pigments such as copper phthalocyanine, halogenated copper phthalocyanines, and metal-free phthalocyanine, anthraquinone-based pigments such as aminoanthraquinone, diaminodianthraquinone, anthrapyrimidine, flavanthrone, anthanthrone, indanthrone, pyranthrone, and violanthrone, quinacridone-bsed pigments, dioxazine-based pigments, perinone-based pigments, perylene-based pigments, thioindigo-based pigments, isoindoline-based pigments, isoindolinone-based pigments, quinophthalone-based pigments, threne-based pigments, and metal complex-based pigments.

Examples of the organic pigment of red include Pigment Red 9, 48, 97, 122, 144, 166, 168, 180, 192, 209, 215, 216, 217, 220, 223, 224, 226, 227, 228, 240, and 254 (all figures are color indices (hereinafter referred to as “CI” numbers)).

Examples of the organic pigment of orange include Pigment Orange 13, 36, 38, 43, 51, 55, 59, 61, 64, 65, and 71.

Examples of the organic pigment of yellow include Pigment Yellow 12, 13, 17, 20, 24, 83, 86, 93, 95, 109, 110, 117, 125, 129, 137, 138, 139, 147, 148, 150, 153, 154, 166, 168, and 185 (all figures are CI numbers).

Examples of the organic pigment of violet include Pigment Violet 23, 30, 32, 40, and 50 (all figures are CI numbers).

Examples of the organic pigment of blue include Pigment Blue 15, 15:3, 15:4, 15:6, 22, 60, or 64 (all figures are CI numbers).

Examples of the organic pigments of green include Pigment Green 7, 10, 36, and 58 (all figures are CI numbers).

Examples of the organic pigment of black include carbon black, perylene black, aniline black, and benzofuranone-based pigments (for example, pigments described in Published Japanese Translation of PTC International Publication for Patent Application No. 2012-515233). Examples of mixed color organic pigments include a pigment prepared by mixing two or more pigments selected from red, blue, green, purple, yellow, magenta, cyan, and the like to form a pseudo blackened pigment.

Examples of the organic pigments of white include titanium dioxide, barium carbonate, zirconium oxide, calcium carbonate, barium sulfate, alumina white, and silicon dioxide.

From the viewpoint of a light shielding property, the (B-1) organic pigment is preferably the black pigment or a pigment exhibiting black color by using two or more of the pigments. As the (B-1) organic pigment, a (B-1a) acid-treated carbon black and a (B-1b) benzofuranone-based organic pigment having an amide structure are preferable.

<(B-1a) Acid-Treated Carbon Black>

Examples of carbon black constituting the (B-1a) acid-treated carbon black include channel black, furnace black, thermal black, acetylene black, and lamp black. From the viewpoint of the light shielding property, the channel black is preferable. By carrying out the surface treatment for introducing the acidic group, the particle surface of the carbon black is acidified to modify the surface state of the particles. This allows the dispersion stability due to the (A) alkali-soluble resin included in the composition to be improved. In addition, the contents of the metal elements and the halogen elements can be easily controlled to the desired range described above.

As The acidic group introduced into the carbon black, substituents exhibiting acidity in the definition of Brønsted are preferable. Specific examples of the substituents include a carboxy group, a sulfonic acid group, and a phosphoric acid group.

The acidic group introduced into the carbon black may form a salt. Examples of the cation that forms the salt with the acidic group include various metal ions, nitrogen-containing compound cations, aryl ammonium ions, alkylammonium ions, and an ammonium ion. From the viewpoint of insulating properties of the cured film, the aryl ammonium ions, the alkylammonium ions, and the ammonium ion are preferable.

Examples of methods for treating the surface for introducing the acidic group to the carbon black include the following methods (1) to (5).

(1) A method of introducing the sulfonic acid group by a direct substitution method of using concentrated sulfuric acid, fuming sulfuric acid, or chlorosulfonic acid or an indirect substitution method of using a sulfite salt or a bisulfite salt.

(2) A method of carrying out the diazo coupling of an organic compound having an amino group and an acidic group and carbon black.

(3) A method of reacting an organic compound having a halogen atom and an acidic group with carbon black having hydroxy group by Williamson's etherification method.

(4) A method of reacting an organic compound having a halogenated carbonyl group and an acidic group protected by a protecting group with carbon black having a hydroxy group.

(5) A method of carrying out Friedel-Crafts reaction of an organic compound having a halogenated carbonyl group and an acidic group protected by a protecting group with carbon black and thereafter deprotecting the acidic group.

Of these methods, the method of (2) is preferable because the introduction treatment of the acidic group is easy and safe. As the organic compound having an amino group and an acidic group used in the method of (2), an organic compound in which the amino group and the acidic group are bonded to the aromatic group is preferable and examples of the organic compound include 4-aminobenzenesulfonic acid and 4-aminobenzoic acid.

The number of moles of the acidic group introduced into carbon black is preferably 1 mmol or larger and more preferably 5 mmol or larger relative to 100 g of the carbon black. The carbon black having the molar number of the acidic group within this range allows the dispersion stability of carbon black to be improved.

On the other hand, the number of moles of the acidic group introduced into the carbon black is preferably 200 mmol or smaller and more preferably 150 mmol or smaller. The carbon black having the molar number of the acidic group within this range allows the dispersion stability of carbon black to be improved.

The content ratio of the (B-1a) acid-treated carbon black included in the solid content of the photosensitive resin composition is preferably 5% by mass or higher, more preferably at 10% by mass or higher, and further preferably 15% by mass or higher. The photosensitive resin composition having the content ratio within this range allows the light shielding property and a toning property to be further improved.

On the other hand, the content ratio of the (B-1a) acid-treated carbon black included in the solid content of the photosensitive resin composition is preferably 70% by mass or smaller, more preferably at 65% by mass or smaller, and further preferably 60% by mass or smaller. The photosensitive resin composition having the content ratio within this range allows the sensitivity during exposure to be improved.

<(B-1b) Benzofuranone-Based Organic Pigment Having Amide Structure>

By including the (B-1b) benzofuranone-based organic pigment having an amide structure, the film obtained from the resin composition can be colored and a coloring property of coloring the light transmitted through the film of the resin composition or the light reflected from the film of the resin composition in desired color can be provided due to stabilization of dispersion by the interaction with the dispersing agent. In addition, the light shielding property of shielding the light having a wavelength absorbed by the (B-1b) benzofuranone-based organic pigment having an amide structure from the light transmitted through the film of the resin composition or the light reflected from the film of the resin composition can be further improved. In addition, the content of the metal elements and the halogen elements can be easily controlled to the desired range described above.

Examples of the (B-1b) benzofuranone-based organic pigment having an amide structure include compounds absorbing light having a wavelength of visible light and coloring in, for example, white, red, orange, yellow, green, blue, or violet. By combining two or more colors of these pigments, the toning property of toning the light transmitted through the film of the resin composition or the light reflected from the film of the resin composition of the desired resin composition into a desired chromatic coordinate can be improved. From the viewpoint of the light shielding property, as the organic pigments having an amide structure, the content ratio of the (B-1b) benzofuranone-based organic pigment having an amide structure included in the solid content of the photosensitive resin composition is preferably 10% by mass or higher. The photosensitive resin composition having this content ratio can further improve the light shielding property. On the other hand, the content ratio is preferably 70% by mass or lower. The photosensitive resin composition having this content ratio can further improve the pattern processability of the photosensitive resin composition.

The (B-1b) benzofuranone-based organic pigment having an amide structure preferably has a structure represented by the following general formula (11) and can further improve the light shielding property. Moreover, the (B-1b) benzofuranone-based organic pigment having an amide structure can improve the toning property by controlling the transmission spectrum or absorption spectrum of the film of the resin composition by, for example, transmitting or shielding the light having a desired specific wavelength due to chemical structure change or functional group conversion. In particular, the (B-1b) benzofuranone-based organic pigment having an amide structure can improve the transmittance of light having a wavelength in the near infrared region (for example, 700 nm or longer).

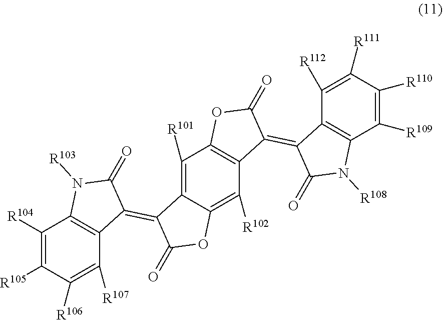

In the general formula (11), R¹⁰¹ and R¹⁰² each independently represent a hydrogen atom, a halogen atom, an alkyl group having a carbon number of 1 to 10, or an alkyl groups having a carbon number of 1 to 10 having 1 to 20 fluorine atoms. R¹⁰⁴ to R¹⁰⁷ and R¹⁰⁹ to R¹¹² each independently represent hydrogen, a halogen atom, an alkyl group having a carbon number of 1 to 10, a carboxy group, a sulfonic acid group, an amino group, or a nitro group. R¹⁰³ and R¹⁰⁸ each independently represent hydrogen, an alkyl group having a carbon number of 1 to 10, or an aryl group having a carbon number of 6 to 15.

Examples of the compound represented by the general formula (11) include “IRGAPHOR (registered trademark)” BLACK S0100CF (manufactured by BASF SE), a black pigment described in WO 2010/081624, or a black pigment described in WO 2010/081756.

The content ratio of the compound represented by the general formula (11) included in the solid content of the negative type photosensitive resin composition is preferably 5% by mass or larger, more preferably 10% by mass or larger, and further preferably 15% by mass or larger. The photosensitive resin composition having the content ratio within this range allows the light shielding property and the toning property to be further improved.

On the other hand, the content ratio of the compound represented by the general formula (11) included in the solid content of the negative type photosensitive resin composition is preferably 70% by mass or lower, more preferably 65% by mass or lower, and further preferably 60% by mass or lower. The photosensitive resin composition having the content ratio within this range allows the sensitivity during exposure to be improved.

<(B-2) Inorganic Pigment>

Examples of the (B-2) inorganic pigment include titanium oxide, zinc white, zinc sulfide, white lead, calcium carbonate, precipitated barium sulfate, white carbon, alumina white, kaolin clay, talc, bentonite, cadmium red, iron oxide, red iron oxide, molybdenum red, molybdate orange, chrome vermilion, chrome yellow, cadmium yellow, yellow iron oxide, titanium yellow, chromium oxide, viridian, titanium cobalt green, cobalt green, cobalt chrome green, Victoria green, ultramarine blue, Prussian blue, cobalt blue, cerulean blue, cobalt silica blue, cobalt zinc silica blue, manganese violet, cobalt violet, graphite, silver-tin alloy, and fine particles, oxides, composite oxides, sulfides, sulfates, nitrates, carbonates, nitrides, carbides, and oxynitrides of metals such as titanium, copper, iron, manganese, cobalt, chromium, nickel, zinc, calcium, and silver. From the viewpoint of improving the light shielding property, as the (B-2) inorganic pigment, fine particles, oxides, composite oxides, sulfides, nitrides, carbides, and oxynitrides of titanium or silver are preferable and the nitride or oxynitride of titanium are more preferable.

The content ratio of the (B-2) inorganic pigment included in the solid content of the photosensitive resin composition is preferably 5% by mass or larger, more preferably at 10% by mass or larger, and further preferably 15% by mass or larger. The photosensitive resin composition having the content ratio within this range allows the light shielding property, heat resistance, and weatherability to be further improved.

On the other hand, the content ratio of the (B-2) inorganic pigment included in the solid content of the photosensitive resin composition is preferably 70% by mass or lower, more preferably 65% by mass or lower, and further preferably 60% by mass or lower. The photosensitive resin composition having the content ratio within this range allows the sensitivity during exposure to be improved.

<(B-3) Dye>

The (B-3) dye refers to a compound for coloring an object by chemical adsorption or strong interaction of the substituent such as an ionic group or a hydroxy group in the (B-3) dye to or with the surface structure of the object. Generally, the (B-3) dye is soluble in a solvent or the like. In addition, coloring with the (B-3) dye has high coloring power and high color development efficiency because the molecules are adsorbed one by one to the object.

By including the (B-3) dyes, the resin composition can be colored in a color having excellent coloring power and thus the coloring property and toning property of the film of the resin composition can be improved.

Examples of the (B-3) dye include Direct Red 2, 4, 9, 23, 26, 28, 31, 39, 62, 63, 72, 75, 76, 79, 80, 81, 83, 84, 89, 92, 95, 111, 173, 184, 207, 211, 212, 214, 218, 221, 223, 224, 225, 226, 227, 232, 233, 240, 241, 242, 243, and 247, Acid Red 35, 42, 51, 52, 57, 62, 80, 82, 111, 114, 118, 119, 127, 128, 131, 143, 145, 151, 154, 157, 158, 211, 249, 254, 257, 261, 263, 266, 289, 299, 301, 305, 319, 336, 337, 361, 396, and 397, Reactive Red 3, 13, 17, 19, 21, 22, 23, 24, 29, 35, 37, 40, 41, 43, 45, 4, and 55, Basic Red 12, 13, 14, 15, 18, 22, 23, 24, 25, 27, 29, 35, 36, 38, 39, 45, and 46, Direct Violet 7, 9, 47, 48, 51, 66, 90, 93, 94, 95, 98, 100, and 101, Acid Violet 5, 9, 11, 34, 43, 47, 48, 51, 75, 90, 103, and 126, Reactive Violet 1, 3, 4, 5, 6, 7, 8, 9, 16, 17, 22, 23, 24, 26, 27, 33, and 34, Basic Violet 1, 2, 3, 7, 10, 15, 16, 20, 21, 25, 27, 28, 35, 37, 39, 40, and 48, Direct Yellow 8, 9, 11, 12, 27, 28, 29, 33, 35, 39, 41, 44, 50, 53, 58, 59, 68, 87, 93, 95, 96, 98, 100, 106, 108, 109, 110, 130, 142, 144, 161, and 163, Acid Yellow 17, 19, 23, 25, 39, 40, 42, 44, 49, 50, 61, 64, 76, 79, 110, 127, 135, 143, 151, 159, 169, 174, 190, 195, 196, 197, 199, 218, 219, 222, and 227, Reactive Yellow 2, 3, 13, 14, 15, 17, 18, 23, 24, 25, 26, 27, 29, 35, 37, 41, and 42, Basic Yellow 1, 2, 4, 11, 13, 14, 15, 19, 21, 23, 24, 25, 28, 29, 32, 36, 39, and 40, Acid Green 16, Acid Blue 9, 45, 80, 83, 90, and 185, and Basic Orange 21 and 23 (all figures are CI numbers).

<(C) Radical Polymerizable Compound>

The (C) radical polymerizable compound refers to a compound having a plurality of ethylenically unsaturated double bonds in the molecule. During exposure, the radical polymerization of the (C) radical polymerizable compound proceeds by the radical generated from the (D) photopolymerization initiator described below and a negative pattern can be formed due to insolubilization of the exposed part of the film of the resin composition to an alkali development liquid.

By including the (C) radical polymerizable compound, the sensitivity during exposure can be improved due to acceleration of UV curing during exposure. In addition, a crosslink density after thermal curing can be increased, and the hardness of the cured product can be improved.

Examples of the (C) radical polymerizable compound include trimethylolpropane tri(meth)acrylate, ditrimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, and dipentaerythritol hexa(meth)acrylate. The photosensitive resin composition may include two or more of these (C) radical polymerizable compounds.

<(D) Photopolymerization Initiator>

The (D) photopolymerization initiator refers to a compound that generates radicals by bond cleavage and/or reaction by exposure. By including the (D) photopolymerization initiator, radical polymerization of the (C) radical polymerizable compound described above proceeds to insolubilize the exposed part of the film of the resin composition to an alkali development liquid. This allows a negative pattern to be formed and, in addition, the sensitivity to be improved by promoting UV curing during exposure.

As the (D) photopolymerization initiator, benzyl ketal-based photopolymerization initiators, α-hydroxyketone-based photopolymerization initiators, α-aminoketone-based photopolymerization initiators, acylphosphineoxide-based photopolymerization initiators, oxime ester-based photopolymerization initiators, acridine-based photopolymerization initiators, titanocene-based photopolymerization initiators, benzophenone-based photopolymerization initiators, acetophenone-based photopolymerization initiators, aromatic keto ester-based photopolymerization initiators, or benzoate-based photopolymerization initiators are preferable. From the viewpoint of increasing the sensitivity during exposure, the α-hydroxyketone-based photopolymerization initiators, the α-aminoketone-based photopolymerization initiators, the acylphosphineoxide-based photopolymerization initiators, the oxime ester-based photopolymerization initiators, the acridine-based photopolymerization initiators, or the benzophenone-based photopolymerization initiators are more preferable and the α-aminoketone-based photopolymerization initiators, the acylphosphineoxide-based photopolymerization initiators, or the oxime ester-based photopolymerization initiators are further preferable.

The content of the (D) photopolymerization initiator included in the photosensitive resin composition used in the present invention is preferably 0.1 part by mass or larger, more preferably 0.5 part by mass or larger, further preferably 0.7 part by mass or larger, and particularly preferably 1 part by mass or larger per 100 parts by mass of the total of the (A) alkali-soluble resin and the (C) radical polymerizable compound. The photosensitive resin composition having the content within this range allows the sensitivity during exposure to be improved.

On the other hand, the content of the (D) photopolymerization initiator is preferably 25 parts by mass or smaller, more preferably 20 parts by mass or smaller, further preferably 17 parts by mass or smaller, and particularly preferably 15 parts by mass or smaller. The photosensitive resin composition having the content within this range allows the resolution after development to be improved and a cured film having a low tapered pattern shape to be obtained.

<Metal or Compound Including Metal Element or Halogen Element>

The photosensitive resin composition used in the present invention may optionally further include a metal or a compound including a metal element or a halogen element, and can control the contents of the metal element and the halogen element in a desired range. Examples of such compounds including the above substances include alkali metals such as sodium and potassium, alkaline earth metals such as barium and calcium, heavy metals such as platinum and iridium, acids such as hydrochloric acid and hydrogen bromide, bases such as sodium hydroxide and potassium hydroxide, inorganic salts such as sodium chloride and potassium chloride, metal complexes such as copper phthalocyanine, and halogenated reagents such as N-chlorosuccinimide and N-bromosuccinimide. The photosensitive resin composition may include those compounds including the above substances as an aqueous solution. From the viewpoint of handling, the photosensitive resin composition preferably includes a trace amount of a diluted aqueous solution of the inorganic salts.

<Dispersing Agent>

The photosensitive resin composition, which is a raw material constituting the pixel division layer and/or the flattening layer preferably further includes a dispersing agent. The dispersing agent refers to a compound having surface affinity groups that interact with the surface of the (B) coloring agent described above and a dispersion stabilizing structure that improves the dispersion stability of the (B) coloring agent. Examples of the dispersion stabilizing structure of the dispersing agent include a polymer chain and/or a substituent having electrostatic charge.

By including the dispersing agent in the photosensitive resin composition, the dispersion stability of the (B) coloring agent is improved and the resolution after development is improved. In particular, for example, in the case where the (B) coloring agent is pulverized particles having a number average particle diameter of 1 μm or smaller, the surface area of the particles of the (B) coloring agent is increased and thus the aggregation of particles of the (B) coloring agent easily occur. On the other hand, in the case of including the (B) coloring agent, the surface of the pulverized (B) coloring agent and surface affinity groups in the dispersing agent interact and steric hindrance and/or electrostatic repulsion by the dispersion stabilizing structure of the dispersing agent inhibits aggregation of particles of the (B) coloring agent, resulting in improving the dispersion stability.

The dispersing agent preferably has a salt-formed structure formed by reacting amino groups and/or acidic groups, which are surface affinity groups, with an acid and/or a base.

Examples of the dispersing agent having the surface affinity groups include “DISPERBYK (registered trademark)”-108, DISPERBYK-109, DISPERBYK-160, DISPERBYK-161, DISPERBYK-162, DISPERBYK-163, DISPERBYK-164, DISPERBYK-166, DISPERBYK-167, DISPERBYK-168, DISPERBYK-182, DISPERBYK-184, DISPERBYK-185, DISPERBYK-2000, DISPERBYK-2008, DISPERBYK-2009, DISPERBYK-2022, DISPERBYK-2050, DISPERBYK-2055, DISPERBYK-2150, DISPERBYK-2155, DISPERBYK-2163, DISPERBYK-2164, and DISPERBYK-2061, and “BYK (registered trademark)”-9075, BYK-9077, BYK-LP-N6919, BYK-LP-N21116, and BYK-LP-N21324 (all product are manufactured by both BYK Japan Co., Ltd.), “EFKA (registered trademark)” 4015, EFKA 4020, EFKA 4046, EFKA 4047, EFKA 4050, EFKA 4055, EFKA 4060, EFKA 4080, EFKA 4300, EFKA 4330, EFKA 4340, EFKA 4400, EFKA 4401, EFKA 4402, EFKA 4403, and EFKA 4800 (all products are manufactured by BASF SE), “Adisper (registered trademark)” PB711 (manufactured by Ajinomoto Fine-Techno Co., Ltd.), “SOLSPERSE (registered trademark)” 13240, SOLSPERSE 13940, SOLSPERSE 20000, SOLSPERSE 71000 and SOLSPERSE 76500 (all products are manufactured by Lubrizol Corporation), “ANTI-TERRA (registered trademark)”-U100 and ANTI-TERRA-204, “DISPERBYK (registered trademark)”-106, DISPERBYK-140, DISPERBYK-142, DISPERBYK-145, DISPERBYK-180, DISPERBYK-2001, DISPERBYK-2013, DISPERBYK-2020, DISPERBYK-2025, DISPERBYK-187, DISPERBYK-191, and “BYK (registered trademark)”-9076 (all products are manufactured by BYK Chemie Japan Co., Ltd.), “Adisper (registered trademark)” PB821, Adisper PB880, and Adisper PB881 (all products are manufactured by Ajinomoto Fine-Techno Co., Ltd.), and “SOLSPERSE (registered trademark)” 9000, SOLSPERSE 11200, SOLSPERSE 13650, SOLSPERSE 24000, SOLSPERSE 32000, SOLSPERSE 32500, SOLSPERSE 32500, SOLSPERSE 32600, SOLSPERSE 33000, SOLSPERSE 34750, SOLSPERSE 35100, SOLSPERSE 35200, SOLSPERSE 37500, SOLSPERSE 39000, SOLSPERSE 56000, and SOLSPERSE 76500 (all products are Lubrizol Corporation).

The amine value of the dispersing agent is preferably 5 mg KOH/g or higher, more preferably 8 mg KOH/g or higher, and further preferably 10 mg KOH/g or higher. The dispersing agent having the amine value within this range allows the dispersion stability of the (B) coloring agent to be improved.

On the other hand, the amine value of the dispersing agent is preferably 150 mg KOH/g or lower, more preferably 120 mg KOH/g or lower, and further preferably 100 mg KOH/g or lower. The dispersing agent having the amine value within this range allows the storage stability of the resin composition to be improved.

Here, the amine value refers to the weight of potassium hydroxide that is equivalent to the acid reacting with per 1 g of dispersing agent and the unit thereof is mg KOH/g. The amine value can be determined by titration with a potassium hydroxide aqueous solution after neutralizing 1 g of the dispersing agent with an acid. The amine equivalent (the unit is g/mol), which is a resin weight of per 1 mol of the amino group, can be calculated from the amine value and the number of amino groups in the dispersing agent can be determined.

The acid value of the dispersing agent is preferably 5 mg KOH/g or higher, more preferably 8 mg KOH/g or higher, and further preferably 10 mg KOH/g or higher. The dispersing agent having the acid value within this range allows the dispersion stability of the (B) coloring agent to be improved.

On the other hand, the acid value of the dispersing agent is preferably 200 mg KOH/g or lower, more preferably 170 mg KOH/g or lower, and further preferably 150 mg KOH/g or lower. The dispersing agent having the acid value within this range allows the storage stability of the resin composition to be improved.

Here, the acid value refers to the weight of potassium hydroxide reacting with per 1 g of dispersing agent and the unit thereof is mg KOH/g. The acid value can be determined by titration of 1 g of dispersing agent with a potassium hydroxide aqueous solution. The acid equivalent (the unit is g/mol), which is a resin weight per 1 mol of the acidic group, can be calculated from the acid value and the number of acidic groups in the dispersing agent can be determined.

Examples of the dispersing agent having polymer chains include acrylic resin-based dispersing agents, polyoxyalkylene ether-based dispersing agents, polyester-based dispersing agents, polyurethane-based dispersing agents, polyol-based dispersing agents, polyethyleneimine-based dispersing agents, and polyallylamine-based dispersing agents. From the viewpoint of pattern processability with the alkali development liquid, the acrylic resin-based dispersing agents, the polyoxyalkylene ether-based dispersing agents, the polyester-based dispersing agents, the polyurethane-based dispersing agents, and the polyol-based dispersing agents are preferable.

<Chain Transfer Agent>

The photosensitive resin composition, which is a raw material constituting the pixel division layer and/or the flattening layer preferably further includes a chain transfer agent. The chain transfer agent refers to a compound that can receive radicals from the polymer growing terminals of the polymer chains obtained by radical polymerization during exposure and can mediate the radical transfer to other polymer chains.

As the chain transfer agent, a thiol-based chain transfer agent is preferable. Examples of the thiol-based chain transfer agents include 1,4-bis(3-mercaptobutanoyloxy)butane, 1,4-bis(3-mercaptopropionyloxy)butane, 1,4-bis(thioglycoyloxy)butane, ethylene glycol bis(thioglycolate), trimethylolethane tris(3-mercaptopropionate), trimethylolethane tris(3-mercaptobutyrate), trimethylolpropane tris(3-mercaptopropionate), trimethylolpropane tris(3-mercaptobutyrate), trimethylolpropane tris(thioglycolate), 1,3,5-tris[(3-mercaptopropionyloxy)ethyl] isocyanurate, 1,3,5-tris[(3-mercaptobutanoyloxy)ethyl] isocyanurate, pentaerythritol tetrakis(3-mercaptopropionate), pentaerythritol tetrakis(3-mercaptobutyrate), pentaerythritol tetrakis(thioglycolate), dipentaerythritol hexakis(3-mercaptopropionate), and dipentaerythritol hexakis(3-mercaptobutyrate). The thiol-based chain transfer agents may include two or more of these compounds.

<Polymerization Inhibitor>

The photosensitive resin composition, which is a raw material constituting the pixel division layer and/or the flattening layer preferably further includes a polymerization inhibitor. The polymerization inhibitor is a compound that traps radicals generated during exposure or radicals of the polymer growing terminals of the polymer chains obtained by radical polymerization during exposure and can stop the radical polymerization by holding these radicals as stable radicals. The photosensitive resin composition including the polymerization inhibitor in an appropriate amount can reduce generation of residual products after development and can improve the resolution after development. This assumes that the progression of excessive radical polymerization is inhibited by trapping the excess amount of the radicals generated during exposure or the radicals of the growing terminals of the chains of the polymer having high molecular weight with the polymerization inhibitor.

As the polymerization inhibitor, phenol-based polymerization inhibitors are preferable. Examples of the phenol-based polymerization inhibitors include 4-methoxyphenol, 1,4-hydroquinone, 1,4-benzoquinone, 2-t-butyl-4-methoxyphenol, 3-t-butyl-4-methoxyphenol, 4-t-butylcatechol, 2,6-di-t-butyl-4-methylphenol, 2,5-di-t-butyl-1,4-hydroquinone, 2,5-di-t-amyl-1,4-hydroquinone, “IRGANOX (registered trademark)” 1010, IRGANOX 1035, IRGANOX 1076, IRGANOX 1098, IRGANOX 1135, IRGANOX 1330, IRGANOX 1726, IRGANOX 1425, IRGANOX 1520, IRGANOX 245, IRGANOX 259, IRGANOX 3114, IRGANOX 565, and IRGANOX 295 (all products are manufactured by BASF SE).

<Sensitizer>

The photosensitive resin composition, which is a raw material constituting the pixel division layer and/or the flattening layer preferably further includes a sensitizer. The sensitizer refers to a compound that can absorb energy generated by exposure, generate excited-triplet electrons by internal conversion and intersystem crossing, and mediate energy transfer to the aforementioned (D) photopolymerization initiator described above. The photosensitive resin composition including the sensitizer allows the sensitivity during exposure to be improved. This assumes that the sensitizer absorbs light having long wavelength that the (D) photopolymerization initiator or the like does not absorb and transfers the energy from the sensitizer to the (D) photopolymerization initiator to improve a photoreaction efficiency.

As the sensitizer, thioxanthone-based sensitizers are preferable. Examples of the thioxanthone-based sensitizers include thioxanthone, 2-methylthioxanthone, 2-chlorothioxanthone, 2-isopropylthioxanthone, 2,4-dimethylthioxanthone, 2,4-diethylthioxanthone, and 2,4-dichlorothioxanthone.

<Crosslinking Agent>

The photosensitive resin composition, which is a raw material constituting the pixel division layer and/or the flattening layer preferably further includes a crosslinking agent. The crosslinking agent refers to a compound having a crosslinkable groups that can bond to the resin. The photosensitive resin composition including the crosslinking agent allows the hardness and chemical resistance of the cured film to be improved. This assumes that an additional crosslinked structure can be introduced into the cured film of the resin composition with the crosslinking agent and thus the crosslinking density increases. As the crosslinking agent, compounds having two or more thermally crosslinkable groups such as an alkoxymethyl group, a methylol group, an epoxy group, and an oxetanyl group are preferable.

The content of the crosslinking agent in the photosensitive resin composition is preferably 0.1 part by mass or larger, more preferably 0.5 part by mass or larger, and further preferably 1 part by mass or larger relative to the 100 parts by mass of the total of the (A) alkali-soluble resin and the (C) radical polymerizable compound. The photosensitive resin composition having the content within this range allows the hardness and chemical resistance of the cured film to be improved.

On the other hand, the content of the crosslinking agent in the photosensitive resin composition is preferably 70 parts by mass or smaller, more preferably 60 parts by mass or smaller, and further preferably 50 parts by mass or smaller. The photosensitive resin composition having the content within this range allows the hardness and chemical resistance of the cured film to be improved.

<Silane Coupling Agent>

The photosensitive resin composition, which is a raw material constituting the pixel division layer and/or the flattening layer preferably further includes a silane coupling agent. The silane coupling agent refers to a compound having a hydrolyzable silyl group or silanol group. The photosensitive resin composition including the silane coupling agent allows the interaction at the interface between the cured film of the resin composition and the substrate serving as a base to increase and adhesiveness of the cured film to the substrate serving as a base and the chemical resistance of the cured film to be improved.

As the silane coupling agent, trifunctional organosilanes, tetrafunctional organosilanes, and silicate compounds are preferable. Examples of the trifunctional organosilanes include methyltrimethoxysilane, methyltriethoxysilane, and methyltri-n-propoxysilane. Examples of the tetrafunctional organosilanes or silicate compounds include organosilanes represented by the following general formula (68).

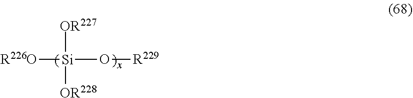

In the general formula (68), R²²⁶ to R²²⁹ each independently represent hydrogen, an alkyl group, an acyl group, or an aryl group and x is an integer of 1 to 15. R²²⁶ to R²²⁹ each independently are preferably hydrogen, an alkyl group having a carbon number of 1 to 6, an acyl group having a carbon number of 2 to 6, or an aryl group having a carbon number of 6 to 15, and more preferably hydrogen, an alkyl group having a carbon number of 1 to 4, an acyl group having a carbon number of 2 to 4, or an aryl group having a carbon number of 6 to 10. The alkyl group, the acyl group, and the aryl group may be either unsubstituted forms or substituted forms.

Examples of the organosilane represented by the general formula (68) include tetrafunctional organosilanes such as tetramethoxysilane, tetraethoxysilane, tetra-n-propoxysilane, tetraisopropoxysilane, tetra-n-butoxysilane, and tetraacetoxysilane and silicate compounds such as methyl silicate 51 (manufactured by Fuso Chemical Co., Ltd.), M silicate 51, silicate 40, silicate 45 (all products are manufactured by Tama Chemicals Co., Ltd.), methyl silicate 51, methyl silicate 53A, ethyl silicate 40, and ethyl silicate 48 (all products are manufactured by Colcoat Co., Ltd.).

<Solvent>

The photosensitive resin composition, which is a raw material constituting the pixel division layer and/or the flattening layer preferably further includes a solvent. The solvent refers to a compound that can dissolve the various resins and various additives to be included in the resin composition. The photosensitive resin composition including the solvent allows various resins and various additives to be included in the resin composition to be uniformly dissolved and thus the transmittance of the cured film to be improved. In addition, the photosensitive resin composition including the solvent allows the viscosity of the resin composition to be arbitrarily controlled and the film having a desired film thickness to be formed on the substrate. In addition, the photosensitive resin composition including the solvent allows a surface tension of the resin composition or drying rate during the application to be arbitrarily controlled and a leveling property during the application and film thickness uniformity of the coated film to be improved.

From the viewpoint of the solubility of various resins and various additives, compounds having an alcoholic hydroxy group, compounds having a carbonyl group, and compounds having three or more ether bonds are preferable as the solvent. In addition, compounds having a boiling point under atmospheric pressure of 110° C. to 250° C. are more preferable as the solvent. The solvent having a boiling point of 110° C. or higher allows the solvent to be adequately volatilized to progress drying of the coated film during the coating. Consequently, unevenness of coating can be reduced and the film thickness uniformity can be improved. On the other hand, the solvent having a boiling point of 250° C. or lower allows the amount of the solvent remaining in the coated film to be reduced and thus the film shrinkage amount during thermal curing can be reduced and the flatness of the cured film is improved, resulting in improving the film thickness uniformity.

In the case where the photosensitive resin composition includes the (B-1) organic pigment as the coloring agent, solvents having a carbonyl group and/or an ester bond are preferable as the solvents. The photosensitive resin composition including the solvent having a carbonyl group and/or an ester bond allows the dispersion stability of the (B-1) organic pigment to be improved. From the viewpoint of the dispersion stability, solvents having an acetate bond are more preferable as the solvents. The photosensitive resin composition including the solvent having an acetate bond allows the dispersion stability of the (B-1) organic pigment to be improved. Examples of the solvent having an acetate bond include 3-methoxy-n-butyl acetate and ethylene glycol monomethyl ether acetate.

In the photosensitive resin composition used in the present invention, the content ratio of the solvent having a carbonyl group and/or an ester bond included in the solvent is preferably in the range of 30% by mass to 100% by mass, more preferably in the range of 50% by mass to 100% by mass, and further preferably in the range of 70% by mass to 100% by mass. The photosensitive resin composition having the content ratio within this range allows the dispersion stability of the (B-1) organic pigment to be improved.

<Other Additives>

The photosensitive resin composition, which is a raw material constituting the pixel division layer and/or the flattening layer preferably may further include other resins or the precursors thereof. Examples of other resins or the precursors thereof include polyamides, epoxy resins, polysiloxane resins, urea resins, polyurethanes, or the precursors thereof.

<Method for Manufacturing Photosensitive Resin Composition>

Representative methods for producing the photosensitive resin composition, which is a raw material constituting the pixel division layer and/or the flattening layer, will be described. In the case of including the (B-1) organic pigment in the (B) coloring agent, for example, the dispersing agent is preferably added to the solution of the (A) alkali-soluble resin, and the (B-1) organic pigment is preferably dispersed into the mixed solution using a dispersing machine to prepare a pigment dispersion liquid. Subsequently, the (C) radical polymerizable compound, the (D) photopolymerization initiator, and other additives and any solvents, if necessary, are preferably added to the pigment dispersion liquid, and the resultant dispersion liquid is preferably stirred for 20 minutes to 3 hours to form a uniform solution. After stirring, the photosensitive resin composition is obtained by filtering the resultant solution.

Examples of the dispersing machine include a ball mill, a bead mill, a sand grinder, a three-roll mill, and a high speed impact mill. From the viewpoints of dispersion efficiency and fine dispersion formation, the bead mill is preferable as the dispersing machine. Examples of the bead mill include a co-ball mill, a basket mill, a pin mill, and a DYNO-mill. Examples of the bead material for the bead mill include titania beads, zirconia beads, and zircon beads. The diameter of the beads used for the bead mill is preferably 0.01 mm to 6 mm, more preferably 0.015 mm to 5 mm, and further preferably 0.03 mm to 3 mm. In the case where the primary particle diameter of the (B-1) organic pigment and the particle diameter of the secondary particles formed by agglomerating the primary particles are several-hundred nanometers or smaller, the fine beads having a bead diameter of 0.015 mm to 0.1 mm is preferable. In this case, the bead mill including a separator operated by a centrifugal separation method that can separate the fine beads and the pigment dispersion liquid is preferable. On the other hand, in the case where the (B-1) organic pigment includes coarse particles having a particle diameter of several-hundred nanometers or larger, the beads having a bead diameter of 0.1 mm to 6 mm are preferable from the viewpoint of dispersion efficiency.

<Optical Density>

In the present invention, the optical density per 1 μm of the thickness of the cured film formed by curing the photosensitive resin composition (hereinafter, referred to as OD) is preferably 0.7 or higher and more preferably 1.0 or higher. The cured film having the optical density within the above range can improve the light shielding property by the cured film. Consequently, a display device such as an organic EL display or a liquid crystal display can further reduce the visibility of electrode wires and external light reflection and thus the contrast of the image display can be improved. On the other hand, the optical density per 1 μm of the thickness of the cured film formed by curing a photosensitive resin composition is preferably 4.0 or lower and more preferably 3.0 or lower. The cured film having the optical density within the above range allows the sensitivity during exposure to be improved. The optical density per 1 μm of the thickness of the cured film formed by curing a photosensitive resin composition can be controlled by the composition and the content ratio of the above-described (B) coloring agent.

<Method for Producing Organic EL Display Device>

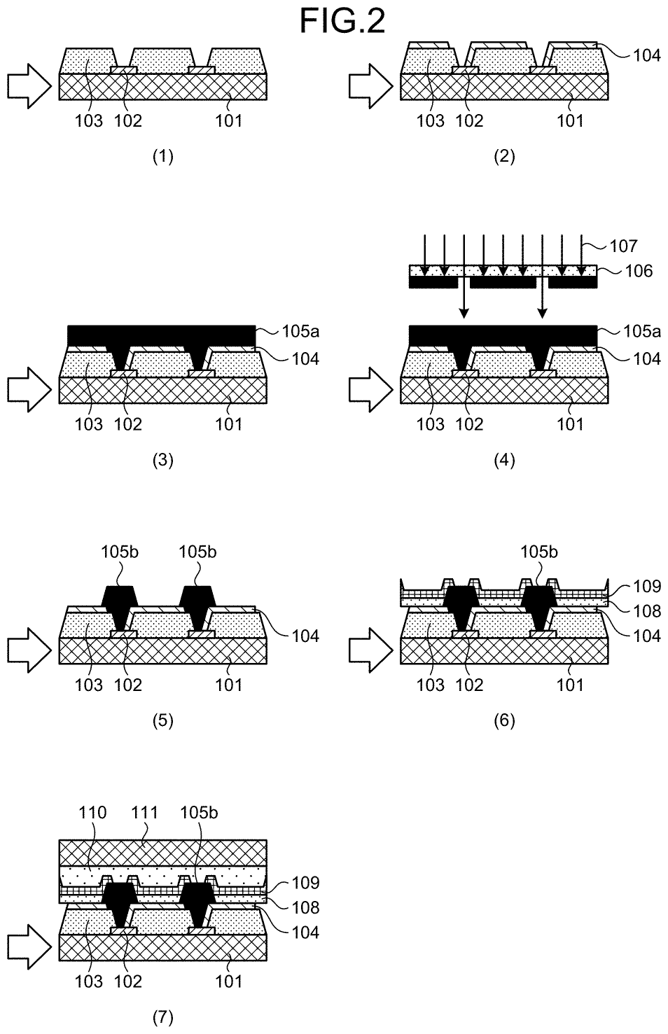

An example of the method for producing the organic EL display device according to the present invention will be described with reference to FIG. 2. In FIG. 2, the cured film of a negative-type photosensitive resin composition is used as the pixel division layer having the light shielding property. Here, (1) to (7) in FIG. 2 correspond to the processes of the following (1) to (7), respectively.

(1) A thin film transistor (hereinafter, referred to as “TFT”) 102 is formed on the glass substrate 101, the film of the photosensitive material for a TFT flattening layer is formed, the resultant film is pattern-processed by photolithography, and thereafter the processed film is thermally cured to form a cured film 103 as the TFT flat flattening layer.

(2) The film of the alloy of magnesium and silver is formed by sputtering, and the resultant film is pattern-processed by etching using a photoresist to form a reflective electrode 104 as the first electrode.

(3) The negative-type photosensitive resin composition according to the present invention is applied and pre-baked to form a pre-baked film 105a.

(4) The pre-baked film 105a is irradiated with active actinic rays 107 through a mask 106 having a desired pattern.

(5) After the irradiated pre-baked film 105a is developed and pattern-processed, the irradiated pre-baked film 105a is subjected to bleaching exposure and middle-baking, if necessary, and thermally cured to form a cured pattern 105b having a desired pattern as the pixel division layer having the light shielding property.

(6) The film of EL light emitting material is formed by evaporation through a mask to form an EL light emitting layer (light emitting pixels) 108, the film of ITO is formed by sputtering, and the ITO film is pattern-processed by etching using a photoresist to form a transparent electrode 109 as the second electrode.

(7) The film of the photosensitive material for the flattening film is formed, the resultant film is pattern-processed by photolithography, thereafter the processed film is thermally cured to form a cured film 110 for flattening, and thereafter, a cover glass 111 is bonded to obtain an organic EL display device.

<Step of Pattern-Processing First Electrode or Second Electrode>

Examples of the method for pattern-processing the first electrode or the second electrode include etching. Hereinafter, a method for pattern-processing the first electrode by etching will be described as an example.

After the material constituting the first electrode is applied onto the substrate, a photoresist is preferably applied onto the first electrode and pre-baked. Thereafter, the pattern of the photoresist is preferably formed on the first electrode by exposing to light and developing the photoresist using photolithography. After development, the obtained pattern is preferably subjected to heat treatment. By the heat treatment, chemical resistance and dry etching resistance are improved by the thermal curing of the photoresist and thus the pattern of the photoresist can be suitably used as an etching mask. Examples of the heat treatment apparatus include an oven, a hot plate, infrared, a flash annealing device, and a laser annealing device. The heat treatment temperature is preferably 70° C. to 200° C. and the heat treatment time is preferably 30 seconds to several hours.

Subsequently, the first electrode is preferably pattern-processed by etching using the pattern of the photoresist as the etching mask. Examples of the etching method include wet etching using an etching liquid and dry etching using an etching gas. Examples of the etching liquid include an acidic or alkaline etching liquid and an organic solvent. The etching liquids may be used in combination of two or more of these etching liquids.

After etching, the pattern of the first electrode can be obtained by removing the remaining photoresist on the first electrode.

<Step of Applying Photosensitive Resin Composition>

Examples of the method for applying the photosensitive resin composition include micro gravure coating, spin coating, dip coating, curtain flow coating, roll coating, spray coating, and slit coating. In addition, examples of the method for applying the photosensitive resin composition in a pattern shape include letterpress printing, intaglio printing, stencil printing, planographic printing, screen printing, inkjet printing, offset printing, and laser printing.

The thickness of the coated film varies depending on the application method and the solid concentration and viscosity of the photosensitive resin composition. The photosensitive resin composition is preferably applied so that the thickness after coating and prebaking is 0.1 μm to 30 μm.

After the photosensitive resin composition is applied, the film of the applied photosensitive resin composition is preferably formed by pre-baking. Examples of heating apparatus used in the pre-baking include an oven, a hot plate, infrared, a flash annealing device, and a laser annealing device. The pre-baking temperature is preferably 50° C. to 150° C. and the pre-baking time is preferably 30 seconds to several hours. The pre-baking may be carried out in two or more stages such as pre-baking at 80° C. for 2 minutes and thereafter pre-baking at 120° C. for 2 minutes.

<Step of Pattern-Processing Photosensitive Resin Composition Film>

Examples of the method for pattern-processing the flattening layer and/or the pixel division layer include a method for directly pattern-processing by photolithography and a method for pattern-processing by etching. From the viewpoints of improving productivity and reducing process time due to reduction in the number of steps, the method for directly pattern-processing by photolithography is preferable.

The pre-baked film of a photosensitive resin composition formed by the method described above is preferably exposed with exposure machines such as a stepper, a mirror projection mask aligner (MPA), or a parallel light mask aligner (PLA). Examples of active actinic rays irradiating during exposure include ultraviolet rays, visible rays, electron beams, X-rays, KrF (wavelength 248 nm) laser, and ArF (wavelength 193 nm) laser. J-line (wavelength 313 nm), i-line (wavelength 365 nm), h-line (wavelength 405 nm), and g-line (wavelength 436 nm) of a mercury lamp are preferably used. The exposure amount is usually about 100 J/m² to about 40,000 J/m² (about 10 J/m² to about 4,000 mJ/cm²) (the value measured with i-line illuminometer) and the pre-baked film can be exposed through a mask having a desired pattern, if necessary.

After exposure, the pre-baked film is preferably developed using, for example, an automatic developing apparatus. The photosensitive resin composition having negative-type photosensitivity allows the unexposed parts to be removed with a development liquid after the development and a relief pattern to be obtained.

As the development liquid, an alkali development liquid or an organic solvent is generally used. As the alkali development liquid, an organic-based alkali solution and an aqueous solution of a compound exhibiting alkalinity are preferable and the aqueous solution of a compound exhibiting alkalinity, that is, the aqueous alkali solution is more preferable from the viewpoint of the environmental aspect.

Examples of the organic-based alkali solution or the compound exhibiting alkalinity include tetramethylammonium hydroxide and tetraethylammonium hydroxide.

Examples of a developing method include a method of applying the development liquid to the film after exposure. The film after exposure is preferably contacted to the development liquid for 5 seconds to 10 minutes.

After the development, the resultant relief pattern is preferably washed with a rinsing liquid. The rinsing liquid is preferably water in the case where the aqueous alkali solution is used as the development liquid.

The pattern-formed photosensitive resin film may be subjected to bleaching exposure. By bleaching exposure, the pattern shape after thermal curing can be adequately controlled and the transparency of the cured film can be improved.

<Step of Obtaining Cured Product of Photosensitive Resin Composition>

The flattening layer and/or the pixel division layer can be formed by thermally curing the photosensitive resin composition film or the pattern thereof. Examples of heat treatment apparatuses used for thermal curing include those exemplified as the heat treatment apparatus used for pre-baking. The heat resistance of the cured film can be improved and a shape having a low tapered pattern can be formed by thermally curing the pattern of the photosensitive resin composition with heating.

The thermal curing temperature is preferably 150° C. or higher and further preferably 250° C. or higher. The photosensitive resin composition thermally cured at the thermal curing temperature within the above range allows the heat resistance of the cured film to be improved and the shape after thermal curing having a lower tapered pattern to be formed. On the other hand, from the viewpoint of reducing take time, the thermal curing temperature is preferably 500° C. or lower and more preferably 400° C. or lower.

The thermal curing time is preferably 1 minute or longer and particularly preferably 30 minutes or longer. The photosensitive resin composition thermally cured for the thermal curing time within the above range allows the shape after thermal curing having a lower tapered pattern to be formed.

<Preparation of Light Emitting Pixel>

The light emitting pixel can be formed by, for example, a mask evaporation method or an inkjet method. Examples of the typical mask evaporation method include a method for patterning by evaporating an organic compound using an evaporation mask, that is, a method in which evaporation is carried out by arranging the evaporation mask having a desired pattern as an opening on the evaporation source side of the substrate.

### EXAMPLES

Hereinafter, the present invention will be more specifically described with reference to Examples and Comparative Examples. Here, for the compounds using abbreviations in the compounds used, names are listed below.

### 4-MOP: 4-Methoxyphenol

### AIBN: 2,2′-Azobis(isobutyronitrile)

BAHF: 2,2-Bis(3-amino-4-hydroxyphenyl)hexafluoropropane
BFE: 1,2-Bis(4-formylphenyl)ethane
BHPF: 9,9-Bis(4-hydroxyphenyl)fluorene
S0100CF: “IRGAPHOR (registered trademark)” BLACK S0100CF (manufactured by BASF SE; benzofuranone based black pigment having a primary particle diameter of 40 nm to 80 nm)
cyEpoTMS: 2-(3,4-Epoxycyclohexyl)ethyltrimethoxysilane

### DBA: Dibenzylamine

DFA: N,N-Dimethylformamide dimethylacetal

### DMF: N,N-Dimethylformamide

DMAEAM: 2-Dimethylaminoethyl methacrylate
DPHA: “KAYARAD (registered trademark)” DPHA (manufactured by Nippon Kayaku Co., Ltd.; dipentaerythritol hexaacrylate)
GMA: Glycidyl methacrylate
ICl: Iodine monochloride
ITO: Indium tin oxide
KI: Potassium iodide
MAA: Methacrylic acid
MMAM: Methyl methacrylate

### MAP: 3-Aminophenol; Meta-aminophenol

MBA: 3-Methoxy-n-butyl acetate

### Mg: Magnesium

### Ag: Silver

NA: 5-Norbornene-2,3-dicarboxylic anhydride; Nadic anhydride
Na₂S₂O₃: Sodium thiosulfate
NCI-831: “ADEKA ARKLS (registered trademark)” NCI-831 (manufactured by ADEKA CORPORATION; 1-(9-ethyl-6-nitro-9H-carbazol-3-yl)-1-[2-methyl-4-(1-methoxypropan-2-yloxy)phenyl]methanone-1-(o-acetyl)oxime)

### NDM: Normal-dodecylmercaptan

NMP: N-Methyl-2-pyrrolidone
ODPA: Bis(3,4-carboxyphenyl) ether dianhydride;
Oxydiphthalic dianhydride
PGMEA: Propylene glycol monomethyl ether acetate
PHA: Phthalic anhydride

### PI: Polyimide

S-20000: “SOLSPERSE (registered trademark)” 20000 (Lubrizol Corporation; polyether-based dispersing agent)
SiDA: 1,3-Bis(3-aminopropyl)tetramethyldisiloxane

### STR: Styrene

TCDM: Tricyclo[5.2.1.0^{2,6}]decan-8-yl methacrylate; Dimethylol-tricyclodecane dimethacrylate

### THF: Tetrahydrofuran

MCS: m-Cresol

### ASL: Anisole

OXAH: Oxalic acid dihydrate
MIBK: Methyl isobutyl ketone, and

### HAD: Formaldehyde.

### Synthesis Example 1 Synthesis of Acrylic Resin

### (AC-1)

In to a three-necked flask, 0.821 g (1 mol %) of AIBN and 29.29 g of PGMEA were charged. Subsequently, 21.52 g (50 mol %) of MAA, 22.03 g (20 mol %) of TCDM, and 15.62 g (30 mol %) of STR were charged and the resultant mixture was stirred at room temperature for a short period. Inside of the flask was sufficiently purged with nitrogen by bubbling and thereafter, the mixture was stirred at 70° C. for 5 hours. Subsequently, a solution in which 14.22 g (20 mol %) of GMA, 0.676 g (1 mol %) of DBA, and 0.186 g (0.3 mol %) of 4-MOP were dissolved into 59.47 g of PGMEA was added to the resulting solution and the obtained solution was stirred at 90° C. for 4 hours to give a solution of an acrylic resin (AC-1). The obtained acrylic resin (AC-1) had a Mw of 15,000, a carboxylic acid equivalent of 500 g/mol, a double bond equivalent of 730 g/mol, and an alkali dissolution rate of 5,500 nm/min.

### Synthesis Example 2 Synthesis of Acrylic Resin (AC-2)

Into a three-necked flask, 200 g of PGMEA was charged. Subsequently, the charged PGMEA was heated to 90° C. and a mixture of 10 g (20 mol %) of DMAEAM, 50 g (50 mol %) of MAA, 20 g (30 mol %) of STR, 8 g (10 mol %) of MMAM, 4 g (1 mol %) of AIBN, and 3 g (1 mol %) of NDM were added dropwise over 3 hours using a pump for dripping, followed by stirring the resultant mixture. Thereafter, the reaction container was purged with air and 20 g (20 mol %) of GMA was added dropwise over 1 hour using a pump for dripping to carry out addition reaction. The obtained mixture was further stirred for 2 hours in the container to give the solution of an acrylic resin (AC-2). The resultant acrylic resin (AC-2) had a Mw of 5,000, an equivalent carboxylic acid amount of 750 g/mol, a double bond equivalent of 600 g/mol, and an alkali dissolution rate of 6,000 nm/min.

### Synthesis Example 3 Synthesis of Cardo-Based Resin (CD-1)

In a three-necked flask, 35.04 g (100 mol %) of BHPF and 40.31 g of MBA were weighed and BHPF was dissolved in MBA. To this solution, a solution in which 27.92 g (90 mol %) of ODPA and 2.96 g (20 mol %) of PHA as the terminal blocking agent were dissolved in 30.00 g of MBA was added and the resultant solution was stirred at 20° C. for 1 hour. Thereafter, the resultant solution was stirred at 150° C. for 5 hours under a nitrogen atmosphere. After completion of the reaction, to the resultant solution, a solution in which 14.22 g (100 mol %) of GMA, 0.135 g (1 mol %) of DBA, and 0.037 g (3 mol %) of 4-MOP were dissolved into 10.00 g of MBA was added and the resultant solution was stirred at 90° C. for 4 hours to give the solution of a cardo-based resin (CD-1). The obtained cardo-based resin (CD-1) had a Mw of 4,000, an equivalent carboxylic acid amount of 800 g/mol, a double bond equivalent of 800 g/mol, and an alkali dissolution rate of 7,000 nm/min.

### Synthesis Example 4 Synthesis of Polyimide Precursor (PIP-1)

In a three-necked flask, 31.02 g (0.10 mol; 100 mol % relative to the total carboxylic acids and the structure units derived from derivatives thereof) of ODPA and 150 g of NMP were weighed and ODPA was dissolved into NMP under dry nitrogen stream. To this solution, a solution in which 25.64 g (0.070 mol; 56.0 mol % relative to the total amine and the structure units derived from derivatives thereof) of BAHF and 1.24 g (0.0050 mol; 4.0 mol % relative to the total amine and the structure units derived from derivatives thereof) of SiDA were dissolved into 50 g of NMP was added and the resultant solution was stirred at 20° C. for 1 hour, and subsequently stirred at 50° C. for 2 hours. Subsequently, to the resultant solution, a solution in which 5.46 g (0.050 mol; 40.0 mol % relative to the total amine and the structure units derived from derivatives thereof) of MAP as the terminal blocking agent was dissolved into 15 g of NMP was added, and the resultant solution was stirred at 50° C. for 2 hours. Thereafter, a solution in which 23.83 g (0.20 mol) of DFA was dissolved into 15 g of NMP was added dropwise over 10 minutes. After completion of the dropwise addition, the resultant solution was stirred at 50° C. for 3 hours. After completion of the reaction, the reaction solution was cooled to room temperature and thereafter poured into 3 L of water and the precipitated solid precipitate was obtained by filtration. The obtained solid was washed with water 3 times and dried in a vacuum oven at 80° C. for 24 hours to give a polyimide precursor (PIP-1). The obtained polyimide precursor (PIP-1) had a Mw of 20,000, an equivalent carboxylic acid amount of 450 g/mol, and an alkali dissolution rate of 400 nm/min.

### Synthesis Example 5 Synthesis of Polybenzoxazole Precursor (PBOP-1)

In a 500 mL round bottom flask equipped with Dean-Stark water separator filled with toluene and a condenser, 34.79 g (0.095 mol; 95.0 mol % relative to the total amine and the structure units derived from derivatives thereof) of BAHF and 1.24 g (0.0050 mol; 5.0 mol % relative to the total amine and the structure units derived from derivatives thereof) of SiDA, and 70.00 g of NMP were weighed and BAHF and SiDA were dissolved into NMP. To this solution, a solution in which 19.06 g (0.080 mol; 66.7 mol % relative to the total carboxylic acids and the structure units derived from derivatives thereof) of BFE was dissolved into 20.00 g of NMP was added and the resultant solution was stirred at 20° C. for 1 hour and subsequently stirred at 50° C. for 2 hours. Subsequently, to the resultant solution, a solution in which 6.57 g (0.040 mol; 33.3 mol % relative to the total carboxylic acids and the structure units derived from derivatives thereof) of NA as the terminal blocking agent was dissolved into 10 g of NMP was added, and the resultant solution was stirred at 50° C. for 2 hours. Thereafter, this solution was stirred at 100° C. for 2 hours under a nitrogen atmosphere. After completion of the reaction, the reaction solution was poured into 3 L of water and the precipitated solid precipitate was obtained by filtration. The obtained solid was washed with water 3 times, dried in a vacuum oven at 80° C. for 24 hours, washed with water 3 times, and dried in a vacuum oven at 80° C. for 24 hours to give a polybenzoxazole precursor (PBOP-1). The obtained polybenzoxazole precursor (PBO-P) had a Mw of 20,000, an equivalent carboxylic acid amount of 330 g/mol, and an alkali dissolution rate of 300 nm/min.

### Synthesis Example 6 Synthesis of Polyimide Resin (PI-1)

In a three-necked flask, 31.13 g (0.085 mol; 77.3 mol % relative to the total amine and the structure units derived from derivatives thereof) of BAHF, 6.21 g (0.0050 mol; 4.5 mol % relative to the total amine and the structure units derived from derivatives thereof) of SiDA, 2.18 g (0.020 mol; 9.5 mol % relative to the total amine and the structure units derived from derivatives thereof) of MAP as the terminal blocking agent, and 150.00 g of NMP were weighed and BAHF, SiDA, and MAP were dissolved into NMP. To this solution, a solution in which 31.02 g (0.10 mol; 100 mol % relative to the total carboxylic acids and the structure units derived from derivatives thereof) of ODPA was dissolved into 50.00 g of NMP was added and the resultant solution was stirred at 20° C. for 1 hour and subsequently stirred at 50° C. for 4 hours. Thereafter, 15 g of xylene was added and the resultant mixture was stirred at 150° C. for 5 hours while the water was being azeotroped with xylene. After completion of the reaction, the reaction solution was poured into 3 L of water and the precipitated solid precipitate was obtained by filtration. The obtained solid was washed with water 3 times and dried in a vacuum oven at 80° C. for 24 hours to give a polyimide resin (PI-1). The obtained polyimide resin (PI-1) had a Mw of 27,000, an equivalent carboxylic acid amount of 350 g/mol, and an alkali dissolution rate of 1,200 nm/min.

### Synthesis Example 7 Synthesis of Polybenzoxazole Resin (PBO-1)

In a 500 mL round bottom flask equipped with Dean-Stark water separator filled with toluene and a condenser, 34.79 g (0.095 mol; 95.0 mol % relative to the total amine and the structure units derived from derivatives thereof) of BAHF, 1.24 g (0.0050 mol; 5.0 mol % relative to the total amine and the structure units derived from derivatives thereof) of SiDA, and 75.00 g of NMP were weighed and BAHF and SiDA were dissolved into NMP. To this solution, a solution in which 19.06 g (0.080 mol; 66.7 mol % relative to the total carboxylic acids and the structure units derived from derivatives thereof) of BFE and 6.57 g (0.040 mol; 33.3 mol % relative to the total carboxylic acids and the structure units derived from derivatives thereof) of NA as the terminal blocking agent were dissolved into 25.00 g of NMP was added and the resultant solution was stirred at 20° C. for 1 hour and subsequently stirred at 50° C. for 1 hour. Thereafter, the resultant solution was heated and stirred at 200° C. or higher for 10 hours under a nitrogen atmosphere to carry out dehydration reaction. After completion of the reaction, the reaction solution was poured into 3 L of water and the precipitated solid precipitate was obtained by filtration. The obtained solid was washed with water 3 times, dried in a vacuum oven at 80° C. for 24 hours, washed with water 3 times, and dried in a vacuum oven at 80° C. for 24 hours to give a polybenzoxazole resin (PRO-1). The obtained polybenzoxazole resin (PBD-1) had a Mw of 25,000, an equivalent carboxylic acid amount of 330 g/mol, and an alkali dissolution rate of 500 nm/min.

### Synthesis Example 8 Synthesis of Novolac Resin

In a three-necked flask, 70.29 g (0.65 mol) of MCS, 37.85 g (0.35 mol) of ASL, 0.62 g (0.005 mol) of OXAH, and 198.85 g of MIRK were weighed and MCS, ASL, and OXAH were dissolved into MIBK. To this solution, 243.49 g (3.00 mol) of HAD (37% by weight aqueous solution) was added and the resultant solution was stirred at 95° C. for 5 hours. Thereafter, the inner temperature was raised to 180° C. over 1 hour and 30 minutes to distil off water from the reaction system. Thereafter, the internal temperature was further raised to 195° C. to remove the unreacted monomers by distilling off the unreacted monomers under a reduced pressure of 150 torr (2.0 kPa). The resin dissolved in the mixed solution was precipitated by cooling the mixed solution to room temperature to give a novolac resin (NL-1). The obtained novolac resin (NL-1) had a Mw of 5,000, an equivalent carboxylic acid amount of 310 g/mol, and an alkali dissolution rate of 400 nm/min.

The compositions of Synthesis Examples 1 to 8 are listed in Table 1 to 7.

TABLE 1

| | | Monomer [Molar ratio] | | | | | | |
|---|---|---|---|---|---|---|---|---|
| | | | | | | Unsaturated | | |
| | | Compound | Compound | Compound | Compound | compound having | Carboxylic | |
| | | having | having | having | having | ethylenical | acid | Double bond |
| | | acidic | basic | aromatic | alicyclic | double bond and | equivalent | equivalent |
| | Polymer | group | group | group | group | epoxy group | [g/mol] | [g/mol] |
| Synthesis | Acrylic | MAA | — | STR | TCDM | DMA | 500 | 730 |
| Example 1 | resin | (50) | | (30) | (20) | (20) | | |
| | (AC-1) | | | | | | | |
| Synthesis | Acrylic | MAA | DMAEAM | STR | | GMA | 750 | 600 |
| Example 2 | resin | (50) | (20) | (30) | | (20) | | |
| | (AC-2) | | | | | | | |

TABLE 2

| | | Monomer [Molar ratio] | | | | | |
|---|---|---|---|---|---|---|---|
| | | | | | Unsaturated | | |
| | | | | | compound | | |
| | | Compound | | | having | | |
| | | having two or | | | ethylenical | Carboxylic | Double |
| | | more aromatic | | Terminal | double bond | acid | bond |
| | | groups and | Tetracarboxylic | blocking | and epoxy | equivalent | equivalent |
| | Polymer | hydroxy group | dianhydride | agent | group | [g/mol] | [g/mol] |
| Synthesis | Cardo- | BHPF | ODPA | PHA | DMA | 800 | 800 |
| Example 3 | based | (100) | (90) | (20) | (100) | | |
| | resin | | | | | | |
| | (CD-1) | | | | | | |

TABLE 3

| | | Monomer [Molar ratio] | | | | Carboxylic | Double |
|---|---|---|---|---|---|---|---|
| | | Tetracarboxylic | | | Terminal | acid | bond |
| | | acid and derivative | Diamine and | | blocking | equivalent | equivalent |
| | Polymer | thereof | derivative thereof | | agent | [g/mol] | [g/mol] |
| Synthesis | Polyimide | ODPA | BAHF | SiDA | MAP | 450 | — |
| Example 4 | precursor | (100) | (70) | (5) | (50) | | |
| | (PIP-1) | | | | | | |

TABLE 4

| | | Monomer [Molar ratio] | | | | | |
|---|---|---|---|---|---|---|---|
| | | Diformyl | Bisaminophenol compound | | | Carboxylic | Double |
| | | compound and | and derivative and | | Terminal | acid | bond |
| | | derivative | dihydroxydiamine and | | blocking | equivalent | equivalent |
| | Polymer | thereof | derivative thereof | | agent | [g/mol] | [g/mol] |
| Synthesis | Polybenzoxazole | BFE | BAHF | SiDA | NA | 330 | — |
| Example 5 | precursor | (80) | (95) | (5) | (40) | | |
| | (PBOP-1) | | | | | | |

TABLE 5

| | | Monomer [Molar ratio] | | | | | |
|---|---|---|---|---|---|---|---|
| | | Tetracarboxylic | | | | Carboxylic | Double |
| | | acid and | Diamine and | | Terminal | acid | bond |
| | | derivative | derivative | | blocking | equivalent | equivalent |
| | Polymer | thereof | thereof | | agent | [g/mol] | [g/mol] |
| Synthesis | Polyimide | ODPA | BAHF | SiDA | MAP | 350 | — |
| Example 6 | resin | (100) | (85) | (5) | (20) | | |
| | (PI-1) | | | | | | |

TABLE 6

| | | Monomer [Molar ratio] | | | | | |
|---|---|---|---|---|---|---|---|
| | | Diformyl | Bisaminophenol compound | | | Carboxylic | Double |
| | | compound and | and derivative and | | Terminal | acid | bond |
| | | derivative | dihydroxydiamine and | | blocking | equivalent | equivalent |
| | Polymer | thereof | derivative thereof | | agent | [g/mol] | [g/mol] |
| Synthesis | Polybenzoxazole | BFE | BAHF | SiDA | NA | 330 | — |
| Example 7 | resin | (80) | (95) | (5) | (40) | | |
| | (PBO-1) | | | | | | |

TABLE 7

| | | | | | Carboxylic | Double |
|---|---|---|---|---|---|---|
| | | Monomer [Molar ratio] | | | acid | bond |
| | | Phenol | Active aromatic | Aldehyde | equivalent | equivalent |
| | Polymer | compound | compound | compound | [g/mol] | [g/mol] |
| Synthesis | Novolac | MCS | ASL | HAD | 310 | — |
| Example 8 | resin | (65) | (35) | (300) | | |
| | (NL-1) | | | | | |

### Preparation Example 1 Preparation of Pigment Dispersion Liquid (Bk-1)

S0100CF as the pigment, the obtained polyimide resin in Synthesis Example 6 (PI-1) as the resin, and S-20000 (DP-1) as the dispersing agent were weighed and mixed so that a mass ratio of pigment/resin/dispersing agent was equal to 60/30/10 (a mass ratio). PGMEA was added as the solvent to the mixture so that the solid concentration was 15% by mass. Into a vertical bead mill filled in a ratio of 75% with zirconia grinding balls having a diameter of 0.10 mm as the ceramic beads for pigment dispersion, the obtained liquid was supplied and treated for 3 hours to give a pigment dispersion liquid (Bk-1) in a mass ratio of pigment/resin/dispersing agent=60/30/10. The number average particle diameter of the pigment in the obtained pigment dispersion liquid was 50 nm. The compositions of Preparation Example 1 are listed in Table 8.

TABLE 8

| | Pigment | | | |
|---|---|---|---|---|
| | dispersion | (A) Alkali- | (B) Coloring | Dispersing |
| | liquid | soluble resin | agent | agent |
| Adjustment | Bk-1 | PI-1 | S0100CF | DP-1 |
| Example 1 | | | | |

Evaluation of the raw materials used in Examples and Comparative Examples and characterizations in Examples and Comparative Examples were carried out in accordance with the following methods.

(1) (A) Weight Average Molecular Weight of Alkali-Soluble Resin

The weight average molecular weight in terms of polystyrene was measured using a GPC analyzer (HLC-8220; manufactured by Tosoh Corporation) and using THF, NMP, or chloroform as a fluidized bed in accordance with “JIS K7252-3: 2008” complying with Low-Temperature Method.

(2) Alkali Dissolution Rate of Alkali-Soluble Resin

A solution in which the resin was dissolved into γ-butyrolactone was applied onto a Si wafer by spin coating at an adequate number of rotations using a spin coater (MS-A100; manufactured by Mikasa Co., Ltd.). Thereafter, the applied resin was pre-baked at 120° C. for 4 minutes using a hot plate (SCW-636; manufactured by DAINIPPON SCREEN MFG. CO., LTD.) to prepare a pre-baked film having a film thickness of 10.0 μm±0.5 μm.

The prepared pre-baked film was developed with a 2.38% by mass TMAH aqueous solution for 60 seconds using a compact development apparatus for photolithography (AC3000; manufactured by TAKIZAWA SANGYO K.K.) and rinsed with water for 30 seconds. The film thickness decrease value after the rinse was calculated in accordance with the following formula as the alkali dissolution rate (the unit is nm/min).

Film thickness decrease value=Film thickness value before development−Film thickness value after development.

(3) (A) Acid Value of Alkali-Soluble Resin

The acid value (the unit is mg KOH/g) was measured by a potentiometric titration method in accordance with “JIS K2501: 2003” using an automatic potentiometric titrator (AT-510; manufactured by KYOTO ELECTRONICS MANUFACTURING CO., LTD.) and using a 0.1 mol/L NaOH/ethanol solution as the titration agent and xylene/DMF=1/1 (a mass ratio) as a titration solvent.

(4) (A) Double Bond Equivalent of Alkali-Soluble Resin

The iodine value of the resin was measured by Wijs method in accordance with “6. Iodine value” in “JIS K0070: 1992” using an automatic potentiometric titrator (AT-510; manufactured by KYOTO ELECTRONICS MANUFACTURING CO., LTD.) and using an ICl solution (a mixed solution of ICl₃=7.9 g, I₂=8.9 g, and AcOH=1,000 mL) as an iodine source, a 100 g/L KI aqueous solution as a trap solution of unreacted iodine, and a 0.1 mol/L Na₂S₂O₃ aqueous solution as a titrant. The double bond equivalent (the unit is g/mol) was calculated from the value of the measured iodine value (the unit is gI/100 g).

(5) OD Value of Pixel Division Layer

The intensities of each incident light and transmitted light of the cured films were measured for the pixel division layer of the organic EL display device obtained by each of Examples and Comparative Examples using an optical densitometer (361TVisual; manufactured by X-Rite, Inc.) and the light shielding OD value was calculated in accordance with the following formula (X).

OD value=log₁₀(I₀/I) Formula (X)

I₀: Incident light intensity

I: Transmitted light intensity.

(6) Amount of Metal Elements and Halogen Elements in Pixel Division Layer

Chlorine ions and lithium ions were injected in amounts of 3.5×10¹⁴ ions/cm² and 1.2×10¹⁴ ions/cm², respectively, into the pixel division layer of the organic EL display device obtained in each Examples and Comparative Examples using IMX-3500RS (manufactured by ULVAC, Inc.) and a relative sensitivity factor (RSF) was calculated.

Based on the obtained relative sensitivity factors, the concentrations of each of the metal elements and halogen elements (target elements) were quantified from TOF-SIMS analysis at around 0.5 μm from the layer surface in the pixel division layer in accordance with the following formula.

Target element concentration=RSF (atom/cm³)×target element ion intensity (counts)/ion intensity of the cured film (counts).

(7) Long Term Reliability of Display Device

The organic EL display device obtained by each Examples and Comparative Examples was allowed to emit light at a DC driving of 10 mA/cm² for 250 hours, 500 hours, and 1000 hours. The area ratio (the pixel light emission area ratio) of the light emitting part relative to the area of the light emitting pixels in each light emitting time was measured. A pixel light emission area ratio after 250 hours, 500 hours, and 1000 hours of 80% or higher can be determined to be excellent long-term reliability and a ratio of 90% or higher is more preferable.

### Example 1

Under yellow light, 0.256 g of NCI-831 was weighed and 10.186 g of MBA was added, followed by stirring the resultant mixture to dissolve. Subsequently, 0.015 g of a 30% by mass MBA solution of the acrylic resin (AC-2) obtained in Synthesis Example 2, 0.285 g of a 30% by mass MBA solution of the polyimide resin (PI-1) obtained in Synthesis Example 6, and 1.422 g of a 80% by mass MBA solution of DPHA were added and the resultant mixture was stirred to give a preparation liquid as a homogeneous solution. Subsequently, 12.968 g of the pigment dispersion liquid (Bk-1) obtained in Preparation Example 1 was weighed, and to this solution, 12.032 g of the preparation liquid obtained above was added and the resultant mixture was stirred to prepare a homogeneous solution. Moreover, 0.01 g of a 5% sodium chloride aqueous solution was added and thereafter the obtained solution was filtered through a filter having a pore diameter of 0.45 μm to prepare a composition 1.

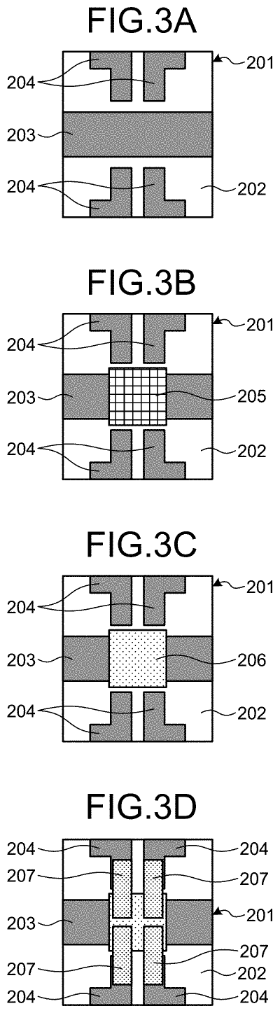

The organic EL display device was prepared by the following method. The preparation procedure will be described with reference to FIGS. 3A to 3D. First, the composition 1 was applied onto the whole surface of an alkali-free glass substrate 201 of 38 mm×46 mm by spin coating using a spin coater (MS-A100; manufactured by Mikasa Co., Ltd.). Thereafter, the applied composition 1 was pre-baked at 100° C. for 120 seconds using a hot plate (SCW-636; manufactured by DAINIPPON SCREEN MFG. CO., LTD.) to prepare a pre-baked film having a film thickness of 2.0 μm.

The whole surface of the prepared pre-baked film was exposed to i-line, h-line, and g-line of an ultra-high pressure mercury lamp through a photomask using a double-side alignment and one-side exposure apparatus (Mask Aligner PEM-6M; manufactured by Union Optical Co., LTD.), and thereafter the exposed pre-baked film was developed with a 2.38% by mass TMAH aqueous solution for 60 seconds using a compact development apparatus for photolithography (AC3000; manufactured by TAKIZAWA SANGYO K.K.) and rinsed with water for 30 seconds. The substrate was thermally cured at 230° C. using a high temperature inert gas oven (INH-9CD-S, manufactured by Koyo Thermo System Co., Ltd.) to prepare a flattening layer 202 having a thickness of about 1.0 μm.

Subsequently, an ITO transparent electric conductive film having a thickness of 100 nm was formed by a sputtering method and etched as a first electrode 203 to form a transparent electrode. In addition, auxiliary electrodes 204 for taking out the second electrodes were also formed at the same time (FIG. 3A). The obtained substrate was washed with ultrasonic wave for 10 minutes using Semico Clean 56 (trade name, manufactured by Furuuchi Chemical Co., Ltd.) and thereafter washed with ultrapure water. Subsequently, the composition 1 was applied onto the whole surface of this substrate by spin coating at an adequate number of rotations using a spin coater (MS-A100; manufactured by Mikasa Co., Ltd.). Thereafter, the applied composition 1 was pre-baked at 100° C. for 120 seconds using a hot plate (SCW-636; manufactured by DAINIPPON SCREEN MFG. CO., LTD.) to prepare a pre-baked film having a film thickness of 2.0 μm.

The prepared pre-baked film was exposed with pattern to i-line, h-line, and g-line of an ultra-high pressure mercury lamp through a photomask having a predetermined pattern using a double-side alignment and one-side exposure apparatus (Mask Aligner PEM-6M, manufactured by Union Optical Co., LTD.), and thereafter the exposed pre-baked film was developed with a 2.38% by mass TMAH aqueous solution for 60 seconds using a compact development apparatus for photolithography (AC3000; manufactured by TAKIZAWA SANGYO K.K.) and rinsed with water for 30 seconds. Thus, a pixel division layer 205, in which the openings having a width of 50 μm and a length of 260 μm were arranged in an interval of 155 μm in a width direction and an interval of 465 μm in a length direction and each opening had a shape exposing the first electrode, was formed only in the specific effective area in the substrate (FIG. 3B). The opening finally becomes a light emitting pixel of the organic EL display device. In addition, the effective area of the substrate (the display area) was determined to be a 16 mm square and the pixel division layer 205 having an opening ratio of 18% was provided. The pixel division layer 205 was formed in a thickness of about 1.0 μm.

The obtained substrate was subjected to nitrogen plasma treatment and thereafter an organic EL layer 206 including a light emitting layer was formed by vacuum evaporation method (FIG. 3C). Here, the degree of vacuum during the evaporation was 1×10⁻³ Pa or lower and the substrate was rotated relative to the evaporation source during the evaporation. First, 10 nm of the compound (HT-1) as the hole injection layer and 50 nm of the compound as the hole transport layer (HT-2) were deposited by evaporation. Subsequently, the compound (GH-1) as the host material and the compound (GD-1) as the dopant material were deposited by evaporation as the light emitting layer at a thickness of 40 nm so that the doping concentration is 10%. Subsequently, the compound (ET-1) as the electron transport material and the compound (LiQ) were stacked at a thickness of 40 nm in a volume ratio of 1:1. The structures of the compounds used in the organic EL layer are illustrated below.

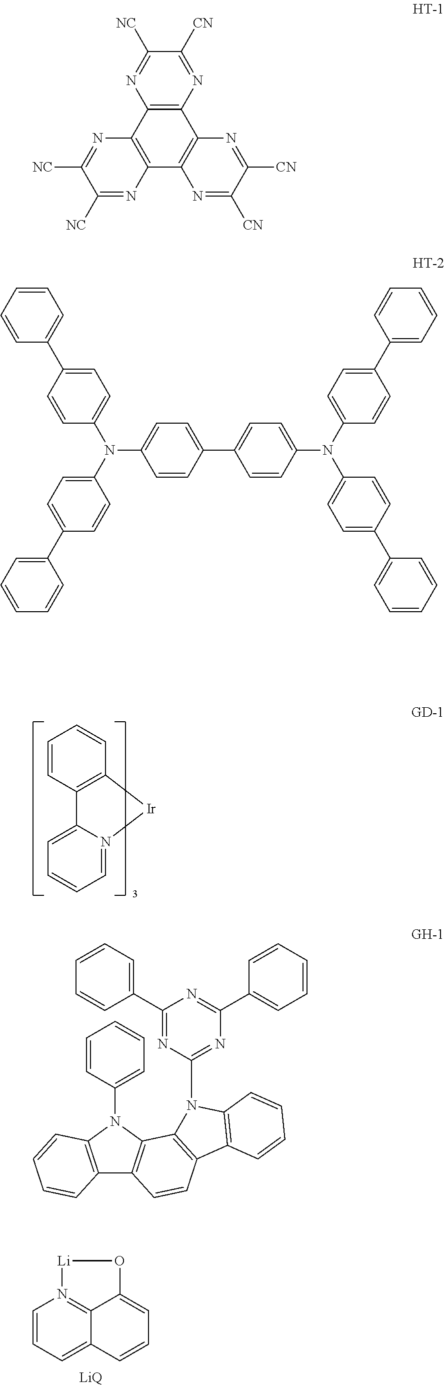

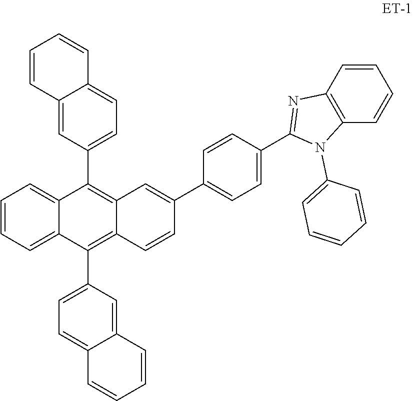 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

Subsequently, the compound (LiQ) was deposited by evaporation at a thickness of 2 nm, and thereafter Mg and Ag were deposited by evaporation at a thickness of 100 nm in a volume ratio of 10:1 to form the second electrodes 207 (FIG. 3D). Finally, sealing was carried out with a cap-shaped glass plate under a low humidity nitrogen atmosphere by bonding using an epoxy resin-based adhesive to prepare four organic EL display devices having a rectangular shape having a side of 5 mm on one substrate. Here, the film thickness as referred to herein is the indicated value in a quartz crystal oscillator type film thickness monitor.

Here, as the optical density, a light shielding OD value was calculated in accordance with the following formula (X) by measuring the intensity of each incident light and transmitted light of the cured film of the organic EL display device using an optical densitometer (361TVisual; manufactured by X-Rite, Inc.).

OD value=log₁₀(I₀/I) Formula (X)

I₀: Incident light intensity

I: Transmitted light intensity.

### Examples 2 to 10

Compositions 2 to 10 were prepared by the same method as the method in Example 1 except that the types and amounts to be added of the (A) alkali-soluble resins used for the photosensitive resin composition were changed as listed in Table 9. Using each of the obtained compositions, the organic EL display device was prepared in the same method as the method in Example 1.

### Comparative Examples 1 to 4

The organic EL display devices were prepared by the same method as the method in Example 1 except that compositions 12 to 15 listed in Table 9 were used instead of the composition 1.

### Example 11

A composition 11 was prepared by the same method as the method in Example 1 except that a 5% aqueous sodium chloride solution was replaced with a 5% aqueous potassium chloride solution in the composition 1. Using the obtained composition 11, the organic EL display device was prepared in the same method as the method in Example 1.

### Examples 12 to 13

The organic EL display devices were prepared by the same method as the method in Example 2 except that the opening ratios in the display area were changed using the composition 2.

### Comparative Example 5

A composition 16 was prepared by the same method as the method in Example 1 except that the amount to be added of the 5% aqueous sodium chloride solution was changed to 0.1 g in the composition 1. Using the obtained composition, the organic EL display device was prepared in the same method as the method in Example 1.

For each of Examples and Comparative Examples, the results of evaluation by the methods described above are listed in Tables 9 to 11. Here, as the driving voltage, voltage during DC driving at 10 mA/cm² was recorded.

TABLE 9

| | | | (A) Alkali-soluble resin | | | |
|---|---|---|---|---|---|---|
| | | | | Carboxylic | | |
| | | | | acid | | |
| | | Pigment | | equivalent | | |
| | Com- | dispersion | | of (A-1) | | (A-1) |
| | pound | liquid | (A-1) | (g/mol) | (A-2) | (wt %) |
| Example 1 | 1 | Bk-1 | AC-2 | 500 | PI-1 | 10 |
| Example 2 | 2 | Bk-1 | AC-1 | 500 | PI-1 | 10 |
| Example 3 | 3 | Bk-1 | PIP-1 | 450 | PI-1 | 10 |
| Example 4 | 4 | Bk-1 | CD-1 | 800 | PI-1 | 10 |
| Example 5 | 5 | Bk-1 | AC-2 | 500 | PI-1 | 30 |
| Example 6 | 6 | Bk-1 | AC-1 | 500 | PI-1 | 30 |
| Example 7 | 7 | Bk-1 | PIP-1 | 450 | PI-1 | 30 |
| Example 8 | 8 | Bk-1 | CD-1 | 800 | PI-1 | 30 |
| Example 9 | 9 | Bk-1 | AC-2 | 500 | PI-1 | 30 |
| Example 10 | 10 | Bk-1 | AC-1 | 500 | PI-1 | 30 |
| Example 11 | 11 | Bk-1 | AC-2 | 500 | PI-1 | 10 |
| Example 12 | 2 | Bk-1 | AC-1 | 500 | PI-1 | 10 |
| Example 13 | 2 | Bk-1 | AC-1 | 500 | PI-1 | 10 |
| Comparative | 12 | Composition described in Example 1 in WO | | | | |
| Example 1 | | 2016/56451 | | | | |
| Comparative | 13 | Composition described in Example 5 in WO | | | | |
| Example 2 | | 2016/158672 | | | | |
| Comparative | 14 | Composition described in Example 1 in Japanese | | | | |
| Example 3 | | Patent Application Laid-open No. H7-198928 | | | | |
| Comparative | 15 | Composition described in Example 1 in Japanese | | | | |
| Example 4 | | Patent Application Laid-open No. 2008-7774 | | | | |
| Comparative | 16 | Bk-1 | AC-2 | 500 | PI-1 | 30 |
| Example 5 | | | | | | |

TABLE 10

| | | Metal Concentration (atom/cm³) | | | | | | | |
|---|---|---|---|---|---|---|---|---|---|
| | | | | | | Alkali | | | |
| | | | | | | metals | | | |
| | | | | | | and | | Halogen | |
| | | | | | Alkaline | alkaline | | concentration | |
| | OD | | | Alkali | earth | earth | | (atom/cm³) | |
| | value | Na | K | metals | metals | metals | Others | Cl | Others |
| Example 1 | 1.0 | 2.0 × 10²¹ | 1.2 × 10¹⁶ | 2.2 × 10²¹ | 1.0 × 10¹⁶ | 2.2 × 10²¹ | 2.2 × 10²⁰ | 1.0 × 10²¹ | 1.0 × 10¹⁶ |
| Example 2 | 1.0 | 2.0 × 10²¹ | 1.2 × 10¹⁶ | 2.2 × 10²¹ | 2.0 × 10¹⁶ | 2.2 × 10²¹ | 2.2 × 10²⁰ | 1.1 × 10²¹ | 2.0 × 10¹⁶ |
| Example 3 | 1.0 | 2.0 × 10²¹ | 1.2 × 10¹⁶ | 2.2 × 10²¹ | 1.2 × 10¹⁶ | 2.2 × 10²¹ | 2.2 × 10²⁰ | 1.0 × 10²¹ | 1.2 × 10¹⁶ |
| Example 4 | 1.0 | 2.0 × 10²¹ | 1.2 × 10¹⁶ | 2.2 × 10²¹ | 2.0 × 10¹⁶ | 2.2 × 10²¹ | 2.2 × 10²⁰ | 1.2 × 10²¹ | 2.0 × 10¹⁶ |
| Example 5 | 1.0 | 2.0 × 10²¹ | 1.2 × 10¹⁶ | 2.2 × 10²¹ | 1.2 × 10¹⁶ | 2.2 × 10²¹ | 2.2 × 10²⁰ | 1.1 × 10²¹ | 1.2 × 10¹⁶ |
| Example 6 | 1.0 | 2.0 × 10²¹ | 1.2 × 10¹⁶ | 2.2 × 10²¹ | 1.0 × 10¹⁶ | 2.2 × 10²¹ | 2.2 × 10²⁰ | 1.0 × 10²¹ | 1.0 × 10¹⁶ |
| Example 7 | 1.0 | 2.0 × 10²¹ | 1.2 × 10¹⁶ | 2.2 × 10²¹ | 2.0 × 10¹⁶ | 2.2 × 10²¹ | 2.2 × 10²⁰ | 1.1 × 10²¹ | 1.2 × 10¹⁶ |
| Example 8 | 1.0 | 2.0 × 10²¹ | 1.2 × 10¹⁶ | 2.2 × 10²¹ | 1.2 × 10¹⁶ | 2.2 × 10²¹ | 2.2 × 10²⁰ | 1.2 × 10²¹ | 1.2 × 10¹⁶ |
| Example 9 | 1.0 | 2.0 × 10²¹ | 1.2 × 10¹⁶ | 2.2 × 10²¹ | 2.0 × 10¹⁶ | 2.2 × 10²¹ | 2.2 × 10²⁰ | 1.1 × 10²¹ | 2.0 × 10¹⁶ |
| Example 10 | 1.0 | 2.0 × 10²¹ | 1.2 × 10¹⁶ | 2.2 × 10²¹ | 1.0 × 10¹⁶ | 2.2 × 10²¹ | 2.2 × 10²⁰ | 1.0 × 10²¹ | 1.0 × 10¹⁶ |
| Example 11 | 1.0 | 1.2 × 10¹⁶ | 2.0 × 10²¹ | 2.2 × 10²¹ | 1.0 × 10¹⁶ | 2.2 × 10²¹ | 2.2 × 10²⁰ | 1.0 × 10²¹ | 1.0 × 10¹⁶ |
| Example 12 | 1.0 | 2.0 × 10²¹ | 1.2 × 10¹⁶ | 2.2 × 10²¹ | 2.0 × 10¹⁶ | 2.2 × 10²¹ | 2.2 × 10²⁰ | 1.1 × 10²¹ | 2.0 × 10¹⁶ |
| Example 13 | 1.0 | 2.0 × 10²¹ | 1.2 × 10¹⁶ | 2.2 × 10²¹ | 2.0 × 10¹⁶ | 2.2 × 10²¹ | 2.2 × 10²⁰ | 1.1 × 10²¹ | 2.0 × 10¹⁶ |
| Comparative | 0.2 | 1.0 × 10¹⁶ | 1.0 × 10¹⁶ | 2.2 × 10¹⁶ | 1.0 × 10¹⁶ | 3.2 × 10¹⁶ | 3.2 × 10¹⁵ | 1.0 × 10¹⁶ | 1.0 × 10¹⁶ |
| Example 1 | | | | | | | | | |
| Comparative | 1.6 | 1.0 × 10¹⁶ | 1.0 × 10¹⁶ | 2.2 × 10¹⁶ | 1.0 × 10¹⁶ | 3.2 × 10¹⁶ | 3.2 × 10¹⁵ | 1.0 × 10¹⁶ | 1.0 × 10¹⁶ |
| Example 2 | | | | | | | | | |
| Comparative | 1.0 | 1.0 × 10¹⁶ | 1.0 × 10¹⁶ | 2.2 × 10¹⁶ | 1.0 × 10¹⁶ | 3.2 × 10¹⁶ | 3.2 × 10¹⁵ | 1.0 × 10¹⁶ | 1.0 × 10¹⁶ |
| Example 3 | | | | | | | | | |
| Comparative | 0.3 | 1.0 × 10¹⁶ | 1.0 × 10¹⁶ | 2.2 × 10¹⁶ | 5.0 × 10¹⁵ | 2.7 × 10¹⁶ | 2.7 × 10¹⁵ | 1.0 × 10¹⁶ | 1.0 × 10¹⁶ |
| Example 4 | | | | | | | | | |
| Comparative | 1.0 | 1.0 × 10²³ | 1.0 × 10¹⁶ | 2.2 × 10¹⁶ | 5.0 × 10¹⁵ | 1.1 × 10²³ | 1.1 × 10²² | 1.0 × 10²³ | 1.0 × 10¹⁶ |
| Example 5 | | | | | | | | | |

| | | Pixel division layer | Driving | Light emitting | | |
|---|---|---|---|---|---|---|
| | Total concentration of | opening ratio | voltage | area ratio (%) | | |
| | metal/halogen | (%) | (V) | 250 hr | 500 hr | 1000 hr |
| Example 1 | 3.4 × 10²¹ | 18 | 4.5 | 90 | 87 | 84 |
| Example 2 | 3.5 × 10²¹ | 18 | 4.5 | 91 | 88 | 85 |
| Example 3 | 3.4 × 10²¹ | 18 | 4.5 | 91 | 88 | 84 |
| Example 4 | 3.6 × 10²¹ | 18 | 4.5 | 86 | 80 | 78 |
| Example 5 | 3.5 × 10²¹ | 18 | 4.5 | 94 | 90 | 88 |
| Example 6 | 3.4 × 10²¹ | 18 | 4.6 | 99 | 98 | 97 |
| Example 7 | 3.5 × 10²¹ | 18 | 4.5 | 98 | 97 | 96 |
| Example 8 | 3.6 × 10²¹ | 18 | 4.5 | 97 | 96 | 95 |
| Example 9 | 3.5 × 10²¹ | 18 | 4.5 | 97 | 96 | 93 |
| Example 10 | 3.4 × 10²¹ | 18 | 4.5 | 95 | 92 | 90 |
| Example 11 | 3.4 × 10²¹ | 18 | 4.5 | 90 | 88 | 86 |
| Example 12 | 3.5 × 10²¹ | 16 | 4.5 | 91 | 88 | 85 |
| Example 13 | 3.5 × 10²¹ | 20 | 4.5 | 91 | 89 | 87 |
| Comparative | 5.5 × 10¹⁶ | 18 | 5.0 | 90 | 80 | 65 |
| Example 1 | | | | | | |
| Comparative | 5.5 × 10¹⁶ | 18 | 5.5 | 90 | 80 | 58 |
| Example 2 | | | | | | |
| Comparative | 5.5 × 10¹⁶ | 18 | 6.0 | 90 | 75 | 56 |
| Example 3 | | | | | | |
| Comparative | 5.0 × 10¹⁶ | 18 | 6.5 | 90 | 75 | 55 |
| Example 4 | | | | | | |
| Comparative | 2.2 × 10²³ | 18 | 4.5 | 90 | 75 | 50 |
| Example 5 | | | | | | |

| | | Concentration | Pixel | | | | |
|---|---|---|---|---|---|---|---|
| | | of | division | | Long-term | | |
| | | metal/ | layer | | reliability | | |
| | | halogen | opening | Driving | Light emitting | | |
| | | (atom/ | ratio | voltage | area ratio (%) | | |
| | Composition | cm³) | (%) | (V) | 250 hr | 500 hr | 1000 hr |
| Example 1 | 1 | 3.4 × 10²¹ | 18 | 4.5 | 90 | 87 | 84 |
| Example 2 | 2 | 3.5 × 10²¹ | 18 | 4.5 | 91 | 88 | 85 |
| Example 3 | 3 | 3.4 × 10²¹ | 18 | 4.5 | 91 | 88 | 84 |
| Example 4 | 4 | 3.6 × 10²¹ | 18 | 4.5 | 86 | 80 | 78 |
| Example 5 | 5 | 3.5 × 10²¹ | 18 | 4.5 | 94 | 90 | 88 |
| Example 6 | 6 | 3.4 × 10²¹ | 18 | 4.5 | 99 | 98 | 97 |
| Example 7 | 7 | 3.5 × 10²¹ | 18 | 4.5 | 98 | 97 | 96 |
| Example 8 | 8 | 3.6 × 10²¹ | 18 | 4.5 | 97 | 96 | 95 |
| Example 9 | 9 | 3.5 × 10²¹ | 18 | 4.5 | 97 | 96 | 93 |
| Example 10 | 10 | 3.4 × 10²¹ | 18 | 4.5 | 95 | 92 | 90 |
| Example 11 | 11 | 3.4 × 10²¹ | 18 | 4.5 | 90 | 88 | 86 |
| Example 12 | 2 | 3.5 × 10²¹ | 16 | 4.5 | 91 | 88 | 85 |
| Example 13 | 2 | 3.5 × 10²¹ | 20 | 4.5 | 91 | 89 | 87 |
| Comparative | 12 | 5.5 × 10¹⁶ | 18 | 5.0 | 90 | 80 | 65 |
| Example 1 | | | | | | | |
| Comparative | 13 | 5.5 × 10¹⁶ | 18 | 5.5 | 90 | 80 | 58 |
| Example 2 | | | | | | | |
| Comparative | 14 | 5.5 × 10¹⁶ | 18 | 6.0 | 90 | 75 | 56 |
| Example 3 | | | | | | | |
| Comparative | 15 | 5.0 × 10¹⁶ | 18 | 6.5 | 90 | 75 | 55 |
| Example 4 | | | | | | | |
| Comparative | 16 | 2.2 × 10²³ | 18 | 4.5 | 90 | 75 | 50 |
| Example 5 | | | | | | | |

### REFERENCE SIGNS LIST

1, 102 TFT
2 Wiring
3 TFT Insulating Layer
4, 202 Flattening Layer
5 ITO
6 Substrate
7 Contact Hole
8, 205 Pixel Division Layer
101, 201 Glass Substrate
103 Cured Film
104 Reflective Electrodes
105a Pre-baked Film
105b Cured Pattern
106 Mask
107 Active Actinic Rays
108 EL Light Emitting Layer
109 Transparent Electrode
110 Cured Film For Flattening
111 Cover Glass
203 First Electrode
204 Auxiliary Electrode
206 Organic EL Layer
207 Second Electrode

1. An organic EL display device comprising:
a photosensitive resin composition comprising an (A) alkali-soluble resin, a (B) coloring agent, a (C) radical polymerizable compound, and a (D) photopolymerization initiator,
wherein the (A) alkali-soluble resin is an (A-1) alkali-soluble resin having a carboxy group;
further a sum of content of at least one of a metal element and a halogen element in a non-volatile component measured by time-of-flight secondary ion mass spectrometry in a cured product formed by curing the photosensitive resin composition is 1×10¹⁷ atom/cm³ or larger and 1×10²² atom/cm³ or smaller; and
in an organic EL element constituted of at least a substrate, a first electrode, a second electrode, a light emitting pixel, a flattening layer, and a pixel division layer, the photosensitive resin composition is arranged in at least one of the flattening layer and the pixel division layer.

2. The organic EL display device according to claim 1, wherein at least one of the metal element and the halogen element is an ionic compound.

3. The organic EL display device according to claim 1, wherein a carboxylic acid equivalent of the (A-1) alkali-soluble resin having the carboxy group is 400 g/mol or higher and 800 g/mol or lower.

4. The organic EL display device according to claim 1, wherein a carboxylic acid equivalent of the (A-1) alkali-soluble resin having the carboxy group is 500 g/mol or higher and 600 g/mol or lower.

5. The organic EL display device according to claim 1, wherein the (A) alkali-soluble resin includes the (A-1) alkali-soluble resin having the carboxy group and an (A-2) alkali-soluble resin having a phenolic hydroxy group; and
a ratio of the (A-1) alkali-soluble resin having the carboxy group included in 100% by weight of a total of the (A-1) alkali-soluble resin having the carboxy group and the (A-2) alkali-soluble resin having the phenolic hydroxy group is in a range of 5% by weight to 40% by weight.

6. The organic EL display device according to claim 1, wherein a cured film has an OD per 1 μm of the cured film of 1.5 or higher.

7. The organic EL display device according to claim 1, wherein a cured film has an OD per 1 μm of the cured film of 1.0 or higher.

8. The organic EL display device according to claim 1, wherein the (A-1) alkali-soluble resin having the carboxy group further includes an (A-1c) alkali-soluble resin having at least one of an amino group and an amide group.

9. The organic EL display device according to claim 1, wherein the (A-1) alkali-soluble resin having the carboxy group is an (A-1a) acrylic resin or an (A-1b) cardo-based resin.

10. (canceled)

11. The organic EL display device according to claim 5, wherein the (A) alkali-soluble resin includes the (A-1) alkali-soluble resin having the carboxy group and the (A-2) alkali-soluble resin having the phenolic hydroxy group; and
the (A-2) alkali-soluble resin having the phenolic hydroxy group is an (A2-a) polyimide resin and an (A-2b) polybenzoxazole resin.

12. The organic EL display device according to claim 5, wherein the (A) alkali-soluble resin includes the (A-1) alkali-soluble resin having the carboxy group and the (A-2) alkali-soluble resin having the phenolic hydroxy group; and
a ratio of the (A-1) alkali-soluble resin having the carboxy group included in 100% by weight of a total of the (A-1) alkali-soluble resin having the carboxy group and the (A-2) alkali-soluble resin having the phenolic hydroxy group is in a range of 5% by weight to 10% by weight.

13. The organic EL display device according to claim 1, wherein a pixel division layer opening ratio in a display area is 20% or lower.

14. The organic EL display device according to claim 1, wherein the metal element is an alkali metal element or an alkaline earth metal element.

15. The organic EL display device according to claim 14, wherein the metal element is the alkali metal element.

16. The organic EL display device according to claim 15, wherein the metal element is at least one of sodium and potassium.

17. The organic EL display device according to claim 1, wherein the halogen element is chlorine.

18. The organic EL display device according to claim 1, wherein a sum of content of at least one of a metal element and a halogen element in a non-volatile component measured by time-of-flight secondary ion mass spectrometry in the photosensitive resin composition is 1×10¹⁷ atom/cm³ or larger and 1×10²⁰ atom/cm³ or smaller.

19. The organic EL display device according to claim 1, wherein the (B) coloring agent is an (B-1) organic pigment.

20. The organic EL display device according to claim 1, wherein the (B-1) organic pigment includes at least one of a (B-1a) acid-treated carbon black and a (B-1b) benzofuranone-based organic pigment having an amide structure.

21. The organic EL display device according to claim 20, wherein the (B-1b) benzofuranone-based organic pigment having the amide structure is a compound represented by the following general formula (11): 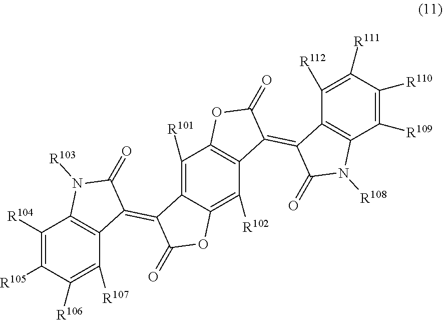
in the general formula (11), R¹⁰¹ and R¹⁰² each independently represent hydrogen, a halogen atom, an alkyl group having a carbon number of 1 to 10, or an alkyl group having a carbon number of 1 to 10 having 1 to 20 fluorine atoms; R¹⁰⁴ to R¹⁰⁷ and R¹⁰⁹ to R¹¹² each independently represent hydrogen, a halogen atom, an alkyl group having a carbon number of 1 to 10, a carboxy group, a sulfonic acid group, an amino group, or a nitro group; and R¹⁰³ and R¹⁰⁸ each independently represent hydrogen, an alkyl group having a carbon number of 1 to 10, or an aryl group having a carbon number of 6 to 15.
